(19) United States
(12) Patent Application Publication
(10) Pub. No.: US 2025/0287731 A1
(43) Pub. Date: Sep. 11, 2025

(54) ULTRAVIOLET LIGHT-EMITTING ELEMENT AND ELECTRIC DEVICE PROVIDED WITH SAME

(71) Applicants: RIKEN, Wako-shi, Saitama (JP); Nippon Tungsten Co., Ltd., Fukuoka-shi, Fukuoka (JP)

(72) Inventors: Noritoshi Maeda, Saitama (JP); Hideki Hirayama, Saitama (JP); Muhamad Ajimal Khan, Saitama (JP); Yasushi Iwaisako, Fukuoka (JP); Hiroyuki OGAMI, Fukuoka (JP); Kengo MOHRI, Fukuoka (JP)

(21) Appl. No.: 18/841,314

(22) PCT Filed: Feb. 15, 2023
(86) PCT No.: PCT/JP2023/005340

§ 371 Date: Apr. 25, 2025

(30) Foreign Application Priority Data
Feb. 24, 2022 (JP) 2022-027061
Jul. 29, 2022 (JP) 2022-121562

(51) Int. Cl. H10H 20/816; H10H 20/81; H10H 20/825

(52) U.S. Cl. CPC H10H 20/8162; H10H 20/8215; H10H 20/825

(57) ABSTRACT

To improve the luminous efficiency of a UV light-emitting device, the UV light-emitting devices disclosed herein have an AlGaN-based crystal or an InAlGaN-based crystal, and comprise an emission layer, at least one electron blocking layer, a first p-type doped layer, and a composition gradient layer in which the Al composition ratio varies depending on the position over a thickness direction of the layer stack, stacked in this order in the direction of the flow of electrons. The Al composition ratio varies depending on the position over the thickness direction in the composition gradient layer. The UV light-emitting devices are implemented as UV-region light-emitting diodes and laser diodes.

### BACKGROUND

### Technical Field

This disclosure relates to an ultraviolet light-emitting element and an electrical device equipped with the same. More specifically, this disclosure relates to an ultraviolet light-emitting element that emits light in the deep ultraviolet range and an electrical device equipped with the same.

### Description of the Related Art

Solid-state light-emitting devices that employ nitride semiconductors are widely used in practical applications, for example as blue light-emitting diodes. Similarly, solid-state light sources are also in demand in the ultraviolet range, so UV light-emitting diodes (UV LEDs) that use materials similar to those used in blue light-emitting diodes are being developed. The wavelength range below 350 nm in the ultraviolet range is also called the deep ultraviolet range (Deep-UV; DUV), and the range from approximately 200 nm to 280 nm is also called the UVC wavelength band. Of these, the wavelength range of around 260 nm to 280 nm is known as the wavelength of sterilization, and there has been vigorous technological development of UV LEDs for this wavelength range. In addition, since deep ultraviolet rays with wavelengths of 222 nm and 254 nm are also expected to have the ability to inactivate SARS-CoV-2, there is a demand for practical solid-state light sources in this area.

In general, deep ultraviolet LEDs (DUV LEDs) are fabricated using the epitaxial growth method with AlGaN or InAlGaN nitride semiconductors, and similar structures using the same processes and materials are also adopted for deep ultraviolet LDs. In AlGaN, which is a compound of AlN and GaN, the band gap corresponding to the wavelength range of approximately 210 nm (AlN) to 360 nm (GaN) is generally achieved according to the ratio of AlN. In InAlGaN, the band gap also changes according to the ratio of AlN in the compound of InN, AlN, and GaN. If we focus on the theoretical aspects alone, it could be possible to create a light-emitting device that emits ultraviolet light in the wavelength range of 210 nm to 360 nm. The current highest external quantum efficiency (EQE) for AlGaN-based deep ultraviolet LEDs is around 20% at a light-emitting wavelength of 275 nm. However, in light-emitting devices made of GaN/AlGaN/InAlGaN-based nitride semiconductors, there is a known issue called the “deep-UV drop-off,” in which the light-emitting efficiency decreases as the wavelength becomes shorter. The deep-UV drop-off, which becomes more serious as the wavelength becomes shorter, is a combination of three issues: firstly, the issue of the nitride semiconductor becoming a semi-insulator in a composition that is suitable for emitting light at short wavelengths; secondly, the issue of the absorption coefficient of GaN increasing; and thirdly, the issue of the TM mode becoming dominant at wavelengths of 230 nm or less.

Specifically, the reason for the difficulty in achieving electrical conduction in the case of semiconductors is attributable to the fact that, in the case of nitride semiconductors with a high aluminum (Al) composition ratio, the activation energy of magnesium (Mg), which is an impurity and an acceptor for p-type conduction, is high, making it difficult to generate holes due to thermal excitation in accordance with the Fermi-Dirac distribution. To address this, a technique called polarization doping (PD) has been proposed (non-patent literature 1-6). PD is a phenomenon in which carriers are induced due to polarization, such as when a hetero-interface is formed in an AlGaN crystal, inducing carriers with two-dimensional spatial extent, or when the composition of AlGaN is made to vary in a gradient manner according to the position over the thickness direction, a phenomenon in which carriers are induced due to polarization, such that carriers with three-dimensional spread are induced across the thickness. It should be noted that PD is merely an expression that likens carrier induction to the effect of doping impurities, and that actual doping substances such as impurities is not always necessary. Non-Patent Document 1 discloses the fundamental aspects of PD. Namely, it is disclosed in Non-Patent Document 1 that in AlGaN crystals grown with nitrogen (N) face (N-face) growth, i.e., AlGaN crystals grown in the [000-1] orientation, a mobile 3D hole gas is induced in the AlGaN composition modulation layer, in which the aluminum (Al) composition increases depending on the position towards the growth direction, and that if Mg is additionally doped into the AlGaN composition modulation layer, it can become a source of holes (holes), are disclosed in Non-Patent Document 1, along with a detailed description of the carrier generation mechanism using PD. Patent Document 1 further discloses that, in the description of the electron gas, which has the opposite polarity to the hole gas, the fact that the three-dimensional mobile electron gas is different from impurity doping in that it does not show thermal dependence and does not freeze even when cooled, and that its mobility is high because there is no scattering by ionic impurities for the same carrier concentration. Non-Patent Document 2 reports on a laser diode that uses an AlN substrate and a PD to achieve room temperature pulsed lasing at a wavelength of 271.8 nm. Non-Patent Document 3 reports on a laser diode that uses a sapphire substrate and a PD to achieve room temperature pulsed lasing at a wavelength of 298 nm. Furthermore, in Non-Patent Document 4, a low-threshold laser diode with a wavelength of 299 nm that uses a sapphire substrate and a ridge waveguide structure for pulsed lasing operation at room temperature is reported. In Non-Patent Document 5, a light-emitting diode in the wavelength band of 280 nm that uses a sapphire substrate and a PD is reported.

### CITATION LIST

### Patent Document(s)

Patent Document 1: WO2011/104969

Patent Document 2: JP 2015-216352 A

### Non-Patent Document(s)

Non-Patent Document 1: J. Simon et al., “Polarization-Induced Hole Doping in Wide-Band-Gap Uniaxial Semiconductor Heterostructures,” Science, Vol.327 pp.60-64 (2010), DOI: 10.1126/science.1183226

Non-Patent Document 2: Ziyi Zhang et al., “A 271.8 nm deep-ultraviolet laser diode for room temperature operation,” Appl. Phys. Express 12 124003 (2019), DOI:10.7567/1882-0786/ab50e0

Non-Patent Document 3: Kosuke Sato et al., “Room-temperature operation of AlGaN ultraviolet-B laser diode at 298 nm on lattice-relaxed Al_{0.6}Ga_{0.4}N/AlN/sapphire,” Appl. Phys. Express 13 031004 (2020), DOI:10.35848/1882-0786/ab7711

Non-Patent Document 4: Shunya Tanaka et al., “Low-threshold-current (˜85 mA) of AlGaN-based UV-B laser diode with refractive-index waveguide structure,” Appl. Phys. Express 14 094009 (2021), DOI:10.35848/1882-0786/ac200b

Non-Patent Document 5: Rie Iwatsuki et al., “Deep UV LED with p-graded AlGaN layer and p-Al_{0.4}Ga_{0.6}N contact layer,” The 82nd JSAP Autumn Meeting 2021, Presentation Abstract, 12p-N101-12

Non-Patent Document 6: Maki Kushimoto et al., “Threshold increase and lasing inhibition due to hexagonal-pyramid-shaped hillocks in AlGaN-based DUV laser diodes on single-crystal AlN substrate,” Jpn. J. Appl. Phys. 61 010601, DOI:10.35848/1347-4065/ac3ald

Non-Patent Document 7: Toshiki Yasuda et al., “Relationship between lattice relaxation and electrical properties in polarization doping of graded AlGaN with high AlN mole fraction on AlGaN template,” Appl. Phys. Express, 10 025502 (2017), DOI:10.7567/APEX.10.025502

Non-Patent Document 8: Shibin Li et al., “Polarization induced pn-junction without dopant in graded AlGaN coherently strained on GaN,” Appl. Phys. Lett. 101, 122103 (2012), DOI:10.1063/1.4753993

Non-Patent Document 9: Mitsuru Funato et al., “Heteroepitaxy mechanisms of AlN on nitridated c- and a-plane sapphire substrates,” J. Appl. Phys. 121, 085304 (2017), DOI:10.1063/1.4977108

### BRIEF SUMMARY

For light-emitting devices in the deep ultraviolet range, there is a continuing need to solve the problem of p-type conduction. While polarization doping (PD) can be a powerful tool for achieving p-type conduction, simply applying PD to a real light-emitting device does not ensure sufficient performance. A novel design concept is vital for improving the light-emitting efficiency of deep ultraviolet light-emitting devices.

The present disclosure addresses the issue of solving at least one of the above problems. The present disclosure contributes to the development of various applications that use deep ultraviolet light-emitting devices as light sources by providing a new structure for deep ultraviolet light-emitting devices that employ PDs for p-type conduction.

The inventors have discovered a specific structure that can further improve the luminous efficiency of deep ultraviolet light-emitting devices that employ PDs for p-type conduction, mainly in terms of carrier injection operation, and have created the disclosure provided herein.

The present inventors conceived that the luminous efficiency could be improved by adopting a combination of an electron blocking layer and a p-type doped layer (first p-type doped layer) together with a composition gradient layer in which the Al composition ratio is varied to achieve PD, and confirmed the improvement effect through experiments. In other words, what is provided in one embodiment of the present disclosure is a UV light-emitting device that includes an AlGaN-based crystal or an InAlGaN-based crystal, comprising, in a stack of the following order in a flow direction of electrons: an emission layer; at least one electron blocking layer; a first p-type doped layer; and a composition gradient layer having an aluminum (Al) composition ratio that varies according to the position over the thickness direction of a layer stack.

In the UV light-emitting device of this disclosure, it is preferable that the direction of the aforementioned electron flow is in the [0001] direction of the AlGaN-based crystal or the InAlGaN-based crystal, and that the composition distribution of the composition gradient layer has a gradient such that the Al composition ratio decreases depending on the position from the side of the first p-type doped layer. In addition, in the UV light-emitting device of the present disclosure, it is also preferable that the minimum value of the Al composition ratio of the composition gradient layer is determined so that the absorption edge wavelength of the composition gradient layer is shorter than the emission peak wavelength of the emission layer. Furthermore, in the present embodiment of the disclosure, electrical equipment that has the UV light-emitting diode described above as a UV light source is also provided.

In this application, the term “deep ultraviolet range (deep-UV; DUV)” refers to ultraviolet light with a wavelength range of 200 nm to 350 nm in a vacuum. The term “principal wavelength of the emitted ultraviolet light” refers to a wavelength that characterizes the emission spectrum of a light-emitting device, which is not necessarily a single wavelength in general, and typically includes the peak wavelength of a single-peak emission spectrum. However, the fact that a wavelength range is described for the principal wavelength does not mean that the wavelength range should encompass the entire emission spectrum. Furthermore, the description of this application may use technical terms that are adopted or borrowed from the fields of electronic devices and physics that deal with visible light and ultraviolet light to explain device structures and functions. For this reason, even when the description is related to electromagnetic waves in the ultraviolet range (ultraviolet rays) that are not visible light, terms such as “photon,” “emission,” “optical-” and “photo-” may be used to explain the operation and radiation phenomena of LEDs (light-emitting diodes) and LDs (laser diodes). The emission layer may include a quantum well layer and a barrier layer. The quantum well layer is a layer that provides electrons with a conduction band edge potential that forms a quantum well, and the barrier layer is a layer that provides a relatively high conduction band edge potential in relation to the quantum well layer. The electron blocking layer is a layer that is provided for the purpose of preventing electron overflow, and is a layer with a raised conduction band edge potential, for example.

In the description of the embodiments of the present disclosure, the p-type doped layer (including the first and second p-type doped layers) is a layer doped with impurities for p-type conduction, and, as is typical for AlGaN-based and InAlGaN system crystals, typically Mg is doped in the p-type doped layer. The Al composition ratio in the p-type doped layer is typically unchanged over the thickness direction, but it is also acceptable for the Al composition ratio to vary. Furthermore, the term polarization doping (PD) used in accordance with convention is also used for phenomena and layers in the case where no impurities are added. In the present embodiment of the LED and LD, the Al composition ratio of the composition gradient layer is varied according to the position over the thickness direction. In other words, the composition gradient layer is an AlGaN or InAlGaN layer in which the Al composition ratio is varied according to the position over the thickness direction. Here, the Al composition ratio is the ratio of AlN in AlGaN (a mixture of AlN and GaN) and InAlGaN (a mixture of InN, AlN, and GaN). In the present embodiment, the change in composition and the layer are referred to as “composition gradient” or “composition gradient layer,” as the change is typically a monotonic increase or decrease depending on the position. However, the change in the Al composition ratio of the composition gradient layer is not limited to a gradient with a constant slope or a gradient with a monotonically changing slope, and can include changes with any increase or decrease, such as a continuous or discontinuous slope.

The UV light-emitting device provided in any of the embodiments of the present disclosure performs light emission with higher efficiency than conventional devices.

### BRIEF DESCRIPTION OF THE SEVERAL VIEWS OF THE DRAWINGS

FIG. 1 is a schematic diagram showing the main components of the light-emitting diode in an embodiment of the present disclosure.

FIG. 2 is a graph showing the Al composition ratio at each position in the film thickness direction from the n-type conductive layer to the second p-type doped layer in an example of the structure of an LED (design wavelength: 230 nm) of an embodiment of the present disclosure.

FIGS. 3A and 3B are graphs showing the Al composition ratio in a comparative example sample to be contrasted with the structure of an embodiment of the present disclosure.

FIGS. 4A-4D show the experimental results of the light emission operation of the sample of the embodiment of the present disclosure and the sample of the comparative example.

FIGS. 4A and 4B show the EL emission intensity spectrum expressed in linear and logarithmic scales, respectively. FIGS. 4C and 4D show the external quantum efficiency expressed in linear and logarithmic scales, respectively.

FIG. 5 is a graph summarizing the current-voltage characteristics and emission characteristics of the sample of the embodiment of the present disclosure and the comparative sample.

FIG. 6 is a graph showing the reflectance spectrum of the reflective electrode of some of the structures of the embodiment of the present disclosure.

FIG. 7 is a graph of the external quantum efficiency when the sample with a modified reflective electrode structure is operated in the embodiment of the present disclosure.

FIGS. 8A-8D are graphs showing the current-voltage characteristics (FIG. 8A), emission spectrum (FIG. 8B), current-output power characteristics (FIG. 8C), and external quantum efficiency (FIG. 8D) when a sample that uses Rh for the reflective electrode is operated in the light-emitting state in an embodiment of the present disclosure.

FIGS. 9A and 9B are graphs showing the transmission spectra of samples in the state before the nitride semiconductor portion is fabricated and electrodes are formed in the structure of the LED in the embodiment of the present disclosure, and are those in the ultraviolet range-visible range (FIG. 9A) and those in the ultraviolet range (FIG. 9B).

FIG. 10 is a schematic diagram showing the outline structure of a laser diode in the embodiment of the present disclosure.

FIG. 11 is a graph showing the Al composition ratio at each position in the thickness direction of an example of the structure of an LD (design wavelength: 280 nm to 290 nm) in the embodiment of the present disclosure, and shows the range from the n-type cladding layer to the second p-type doped layer.

FIGS. 12A and 12B show the results of performance confirmation when a sample with a structure of an LD fabricated by changing the impurity concentration of the p-type waveguide (WG) layer in an embodiment of the present disclosure is operated as an LED performance confirmation results, which are the EL emission spectrum (FIG. 12A) in continuous operation (CW operation) at room temperature and the external quantum efficiency (FIG. 12B) calculated from the emission intensity in pulse operation at room temperature.

FIGS. 13A and 13B are explanatory diagrams to explain the presumed effects of the composition gradient layer of the embodiment of the present disclosure, and FIGS. 13A and 13B show the main parts of a comparative example LED in which a Mg-doped AlGaN layer with a constant Mg-doped AlGaN layers with a constant Al composition ratio are used instead of composition gradient layers, and the main parts of each of the comparative example LEDs and the example LEDs with a composition gradient layer that is not Mg-doped are shown.

FIGS. 14A and 14B are an illustration showing the profile of the Al composition ratio in one of the quantum well layers (FIG. 14A) and a graph showing the current characteristics of the external quantum efficiency measured from samples of each structure (FIG. 14B).

FIG. 15 is a graph showing the actual measured external quantum efficiency of samples before and after improving the AlN template and n-type conductive layer.

FIGS. 16A-16C show the EL emission intensity spectrum (FIG. 16A), current-light output characteristics (FIG. 16B), and current external quantum efficiency characteristics (FIG. 16C) obtained in an example sample employing a p-GaN contact layer in an embodiment of the present disclosure, in contrast to a sample with a structure that does not apply optimization of the quantum well layer structure for increasing the TE mode ratio. contact layer in the embodiment sample obtained in the embodiment of the present disclosure, including the EL emission intensity spectrum (FIG. 16A), the current-light output characteristics (FIG. 16B), and the current external quantum efficiency characteristics (FIG. 16C).

FIG. 17 is a graph showing the current external quantum efficiency and current-light output characteristics measured from the embodiment sample in the embodiment of the present disclosure.

FIGS. 18A-18D are graphs showing the layer structure of an LED with a structure similar to that of the embodiment of the present disclosure (FIG. 18A), a structure in which the first p-type doped layer 140 is divided into two over the thickness direction, and only the composition gradient layer side is modulated doped with Mg (FIG. 18B), a composition gradient layer with a slower composition gradient (FIG. 18C), and a combination of modulated doping and a slower composition gradient (FIG. 18D) are shown in a graph according to the Al composition ratio.

FIG. 19 is a graph of the external quantum efficiency measured for samples with the structures shown in FIGS. 18A to 18D.

FIGS. 20A-20C are graphs showing the performance measurements for the structure of the combination of modulated doping and slow composition gradient shown in FIG. 18D, and show the EL spectrum (FIG. 20A), external quantum efficiency (FIG. 20B), and light output characteristics (FIG. 20C)

FIGS. 21A-21D are a time chart of the Al composition ratio in the growth process when a steep composition gradient and a normal gradient composition are adopted for the composition gradient layer (FIG. 21A), and steep composition gradient, and the graphs show the EL spectrum (FIG. 21B), external quantum efficiency (FIG. 21C), and light output characteristics (FIG. 21D).

FIG. 22 shows the EL spectra measured at each current value for a sample of the LD of the embodiment of the present disclosure.

FIGS. 23A and 23B show the current-voltage characteristics (FIG. 23A) and the current-emission intensity characteristics (FIG. 23B) measured for the same sample as FIG. 22.

FIGS. 24A and 24B are graphs showing the layer structure of the LD of the embodiment of the present disclosure, in a structure without an electron blocking layer, with the p-side WG layer undoped (FIG. 24A) and with the p-side WG layer 8-doped (FIG. 24B), according to the Al composition ratio.

FIGS. 25A-25C are graphs showing the Al composition ratio for the structure in which an electron blocking layer is used and the p-side WG layer is doped at a constant concentration over the thickness of the p-side WG layer (FIG. 25A), the structure in which the doping is repeated to increase and decrease to create a modulated concentration profile (FIG. 25B), and the structure in which the Al composition ratio is repeatedly increased and decreased in addition to the repeated modulation of the p-type dopant (FIG. 25C). concentration profile (FIG. 25B) and a structure in which the Al composition ratio is repeatedly increased and decreased in addition to the repeated modulation of the p-type dopant (FIG. 25C).

FIGS. 26A and 26B are graphs showing the external quantum efficiency (FIG. 26A) and current-voltage characteristics (FIG. 26B) measured for each sample of the structures shown in FIGS. 25A to 25C.

### DETAILED DESCRIPTION

The following describes the deep ultraviolet light-emitting device pertaining to the present disclosure. In the present embodiment, the embodiments of a light-emitting diode (LED) and a laser diode (LD) are described. Unless otherwise noted in the description, common parts or elements are given a common reference symbol. In addition, the elements of each embodiment in the drawings are not necessarily drawn to scale with each other.

### 1. Embodiment of a Light-Emitting Diode

In the present embodiment of LED 100, the p-type conduction performance is enhanced, and the luminous efficiency is improved by adopting an electron blocking layer 138, a first p-type doped layer 140, and a composition gradient layer 150 on the side of the reflective electrode 160 as seen from the emission layer 134. The structure of the LED 100 of the present embodiment is as follows.

### 1-1. Structure of the LED 100 in the Present Embodiment

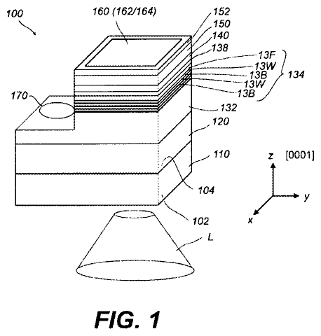

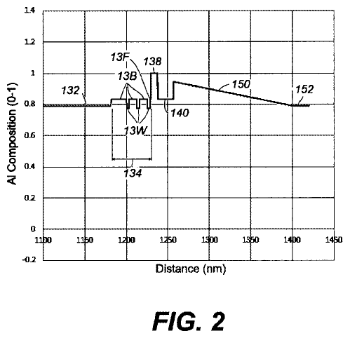

FIG. 1 is a schematic diagram showing the main components of the LED 100 of the present embodiment. FIG. 2 is a graph showing the Al composition ratio at each position in the thickness direction of the n-type conductive layer 132 to the second p-type doped layer 152 in an example of the structure of the LED 100 of the present embodiment (design wavelength: 230 nm). The symbols used in FIG. 1 are supplied in the graph.

As shown in FIG. 1, in a typical structure of LED 100, a buffer layer 120 is epitaxially grown on one side 104 of a substrate 110, which is a flat c-plane α-Al₂O₃ single crystal (sapphire), using a material such as AlN crystal. A series of layers is then formed on the side of the buffer layer 120, in the following order: n-type conductive layer 132, emission layer 134, electron blocking layer 138, first p-type doped layer 140, composition gradient layer 150, second p-type doped layer 152, and reflective electrode 160, which acts as the second electrode. The materials of the n-type conductive layer 132 to the second p-type doped layer 152 are typically AlGaN or InAlGaN, or a composition to which trace elements (or impurities, Si for n-type, Mg for p-type) are added as necessary. The n-type conductive layer 132 is electrically connected to the first electrode 170. The reflective electrode 160 establishes an electrical connection with the second p-type doped layer 152. The light output L, which is UV radiation, is typically emitted from the other side of the substrate 110, the light extraction surface 102. When the light-emitting device of the present embodiment is operated as a light-emitting diode, the UV light that is emitted and travels towards the reflective electrode 160 is also reflected and extracted from the light extraction surface 102.

The structure of each layer is explained in more detail. Substrate 110 is a growth substrate that can be used for epitaxial growth of n-type conductive layer 132 to second p-type doped layer 152. The substrate 110 is typically a c-plane sapphire substrate, and when x-y coordinates are defined so that one surface 104 and the light extraction surface 102 are in the x-y plane, the z-axis direction becomes the direction of crystal growth, i.e., the direction over the thickness direction of the layers. The growth orientation of the n-type conductive layer 132 to the second p-type doped layer 152 is, for example, [0001] axis orientation of AlGaN crystals. During crystal growth, it is possible to grow on Ga-face, where Ga or Al of the AlGaN is exposed on the surface. The substrate 110 of the present embodiment can be selected from any material that meets the conditions for growth, such as the crystal orientation and heat resistance. In addition to the sapphire mentioned above, it can be an AlN single crystal substrate or a Ga₂O₃ substrate in the case of radiation UV with a wavelength of 300 nm or more. For the substrate 110 of the present embodiment, the crystal plane orientation is selected as appropriate, such that the growth orientation of the n-type conductive layer 132 to the second p-type doped layer 152 is, for example, [0001] axis orientation of the AlGaN crystal in the growth direction, and if necessary, one with an off-angle is also used. In the typical structure described above, the substrate 110 is made by growing crystals in the [0001] direction using the c-plane of one side 104 of the substrate 110. The LED 100 mainly extracts light in a direction opposite to the growth direction, and there are two possible structures: one in which the substrate 110 remains in the final operating state, and one in which the substrate 110 is not present. If the substrate 110 is still remaining in the LED 100 during final operation, the substrate 110 is also required to be permeable to radiated UV in order to function as an LED. The arrangement of the first electrode 170 can be different from that shown in FIG. 1 as long as it can be electrically connected to the n-type conductive layer 132, when a material that can be expected to be conductive, such as a Ga₂O₃ substrate, is used for the substrate 110.

The buffer layer 120 is carefully selected to satisfy the requirement of crystal growth to increase the internal quantum efficiency η_{IQE}, and, for example, a crystal of a high-quality AlGaN layer, AlN layer, or InAlGaN layer is formed on the substrate 110. The buffer layer 120 is formed as a single layer or a multilayer as needed, and is formed to a thickness of about 2 μm, for example.

The n-type conductive layer 132 is, in a typical structure when an AlGaN layer is used, for example, an Al_{0.85}Ga_{0.15}N layer to which Si has been doped as an impurity to make it n-type, that is, an Al_{0.85}Ga_{0.15}N; Si layer.

The emission layer 134 is a layer in which quantum levels for emission are formed, and it is made up of alternating layers of barrier layer 13B and quantum well layer 13W, with the last barrier layer called the final barrier (FB) layer 13F. Therefore, the structure of the MQW (multi-quantum well) stack is as follows: barrier layer 13B,quantum well layer 13W, barrier layer 13B, . . . , quantum well layer 13W, and final barrier (FB) layer 13F, from the side of the n-type conductive layer 132. Therefore, the quantum well layer 13W includes two or more quantum well layers 13W, for example, and the barrier layer 13B is sandwiched between the two quantum well layers 13W. The emission layer 134 is made of a composition such as Al_{0.94}Ga_{0.06}N for the barrier layer 13B and Al_{0.82}Ga_{0.18}N for the quantum well layer 13W. The number of other typical quantum wells is, for example, two, three, or four. In a structure where the final barrier layer 13F is not used, one of the quantum well layers 13W is located on the electron blocking layer 138 side of the emission layer 134.

The FB layer 13F is formed following the quantum well layer 13W as necessary. In the LED 100, the typical FB layer 13F is a very thin layer. In the structure example shown in FIG. 2, it has a thickness of about 1 nm. The purpose of forming the FB layer 13F is not particularly limited. Typical examples of this purpose include: to prevent the energy values of the levels confined to the nearest quantum well layer 13W from being affected by the high conduction band edge potential of the electron blocking layer 138, which is attributable to the electron blocking layer 138 being too close to the emission layer 134, or to use the FB layer 13F as an intermediate layer for crystal growth of the quantum well layer 13W as a hetero-interface. The FB layer 13F is an undoped AlGaN layer, and the Al composition ratio of the FB layer 13F is typically matched to the value of the barrier layer 13B, and its thickness is adjusted as appropriate.

The electron blocking layer 138 in LED 100 is a layer that serves to suppress electron overflow, and this is achieved by the conduction band edge, which acts as a high barrier to electrons. This overflow is a phenomenon in which a current that does not contribute to luminescence flows because some of the carriers pass through the emission layer 134 without contributing to the intended recombination, and it is a problem for electrons in nitride semiconductors. The electron blocking layer 138 is typically a single layer of AlN or an Al-rich AlGaN. The electron blocking layer 138 is separated from the last quantum well layer 13W of the emission layer 134 by only the FB layer 13F, which is provided as necessary. In the LED 100, the electron blocking layer 138 is located close to the emission layer 134 because this location is suitable for suppressing electron overflow. If the electron blocking layer 138 can suppress electron overflow, it will be possible to directly form a layer that induces holes and is responsible for p-type conduction in a position following the electron blocking layer 138.

In the present embodiment, the first p-type doped layer 140 and the second p-type doped layer 152 (if present) can be p-type AlGaN or p-type InAlGaN doped with Mg in AlGaN or InAlGaN material. If the second p-type doped layer 152 is sufficiently doped with acceptor impurities, it becomes a degenerate semiconductor, making it easier to achieve ohmic contact. The Al composition ratio of the first p-type doped layer 140 and the second p-type doped layer 152 is formed to be uniform over the thickness direction.

The composition gradient layer 150 is also made of AlGaN or InAlGaN, but the Al composition ratio varies depending on the position over the thickness direction. This causes the composition gradient layer 150 to have insufficient cancellation of spontaneous polarization at each position within the crystal, thereby inducing carriers. In a structure where the crystal is grown in

direction and electrons flow in that direction, if the Al composition ratio is made to decrease over the thickness direction from the first p-type doped layer 140, the induced carriers are holes, and p-type conductivity is increased.

In order to increase the light extraction efficiency (Light Extraction Efficiency; LEE) of the LED, if the Al composition ratio is appropriately selected throughout the entire semiconductor portion of the LED 100, it is possible to achieve high transmittance for the emitted UV. In particular, the present inventors have disclosed that the transmittance of the p-type layer with respect to the emission wavelength is important for the LED (Patent Document 2). In the present embodiment, it is preferable to give the composition gradient layer 150 transmissivity at the emission wavelength by making the absorption edge wavelength of the composition gradient layer 150 shorter than the emission peak wavelength of the emission layer 134 when determining the minimum Al composition ratio.

When an InAlGaN layer containing indium (In) is used for the emission layer 134, a structure similar to this can be adopted for each of the n-type conductive layer 132 to the FB layer 13F. Even if an InAlGaN layer is used for the emission layer 134, the structure can be such that no other layers than the emission layer 134 contain In.

The first electrode 170 is a metal electrode consisting of a multilayer film of Ni and Au (Ni/Au composite layer) in order from the substrate side. The Ni is a layer of, for example, 25 nm thickness inserted between the Au and the underlying semiconductor layer to enable ohmic contact. The second electrode is a reflective metal electrode (reflective electrode) 160, which uses a UV reflective film 164 that exhibits high reflectivity to UV radiation. This UV reflective film 164 is a film made of a material that contains Al and Rh as its main components. For ohmic contact, an inserted metal layer 162 that is part of the reflective electrode is also inserted into the reflective electrode 160 as necessary. Therefore, a typical structure of the reflective electrode 160 is a metal electrode (Ni/Al composite layer) with a layered structure in which the Rh single layer or the inserted metal layer 162 and the UV reflective film 164 are Ni and Al in order.

### 1-2. Improved Polarization Doping in the Present Embodiment

In the present embodiment, which employs a quantum well, in the quantum confinement state of the quantum well layer 13W formed in the emission layer 134, electrons are injected from the n-type conductive layer 132 via the conduction band, and holes are injected from the composition gradient layer 150 via the valence band. The electrons and holes recombine each other in the quantum well according to the interband transition and emit ultraviolet light. In the structure of conventional nitride semiconductor LEDs, the activation energy of Mg, which is an impurity that acts as a p-type dopant, is high in the band structure that is suitable for deep ultraviolet range emission, making thermal excitation difficult. Non-Patent Document 7 discloses experimental results that suggest that when a composition gradient layer is made of undoped AlGaN crystal using simple polarization doping, the conductivity type is not p-type but n-type, inducing electrons. Although Non-Patent Document 7 does not discuss this experimental result, the inventors believe that the composition gradient layer is p-type, inducing holes. In other words, in Non-Patent Document 7, the conductivity is stated to be n-type, just like electrons, as a result of the Hall effect measurement. However, the inventors believe that some kind of error is occurring in the Hall effect measurement of transverse current in Non-Patent Document 7, because in the vertical Hall current devices such as pn junction diodes and LDs disclosed in Non-Patent Document 8, the composition gradient layer that employs simple polarization doping actually functions as a p-type layer. For example, it is thought that electrons are induced in the layer that forms the underlying layer of the composition gradient layer (AlGaN layer), and that this is detected as n-type conductivity in the Hall effect, but that it is actually the holes that are induced in the composition gradient layer that perform the p-type conductivity.

In the present embodiment of the LED 100, the combination of improved polarization doping (PD) achieves both sufficiently enhanced electrical conductivity and high luminous efficiency. The improved PD is achieved by combining an electron blocking layer 138, a first p-type doped layer 140, and a composition gradient layer 150. In addition, a second p-type doped layer 152 can be adopted as an option. In the structure of the LED 100, the Al composition ratio in the composition gradient layer 150 is higher on the side of the first p-type doped layer 140 and lower on the side of the reflective electrode 160. As described above, in the combination of this composition gradient in the above-mentioned direction and crystal growth in the [0001] direction (C-axis direction), the carriers induced in the composition gradient layer 150 are holes for p-type conduction. The present inventors suppose that when the impurities doped in the layer adjacent to the composition gradient layer 150 in the [000-1] direction (-C axis) (in the present embodiment, the first p-type doped layer 140) are activated as acceptors, the generated holes induce holes with a positive conductivity type in the composition gradient layer 150 as well. Therefore, the position for doping the impurity (Mg) is the layer adjacent to the undoped composition gradient layer (composition gradient layer 150) in the -C axis direction, and this can be made to match the doping position described in non-Patent Document 1 as a remote acceptor state. The Al composition ratio on the first p-type doped layer 140 side of the composition gradient layer 150 is typically higher than that of the first p-type doped layer 140.

Mg is added as an impurity dopant to the first p-type doped layer 140 and the second p-type doped layer 152. The first p-type doped layer 140 is separated from the emission layer 134 and the FB layer 13F by the electron blocking layer 138. As a result, the first p-type doped layer 140 can act as a source of holes that are located in a position relatively close to the emission layer 134. In other words, the first p-type doped layer 140 serves to improve the efficiency of electron injection. In typical cases, the Al composition ratio of the first p-type doped layer 140 is made smaller than that of the composition gradient layer 150 in a position directly contacting the first p-type doped layer 140, because if the Al composition ratio is made smaller within a range that does not affect UV transmissivity, it becomes easier to activate Mg and increase the carrier concentration. The second p-type doped layer 152 also serves to ensure the transmission of light wavelengths while maintaining conductivity with the reflective electrode 160. There are no particular limitations on the thickness of the first p-type doped layer 140 as long as it is used as an LED. The amount of impurity Mg doped into the first p-type doped layer 140 is set so that the acceptor concentration of the layer is, for example, about 10¹⁸ cm⁻³.

The specific structure of each semiconductor layer in the example LED 100 structure shown in FIG. 2 is as follows.

TABLE 1

| | Al Composition | Thickness | |
|---|---|---|---|
| Layer (with ref numeral in FIG. 2) | Ratio (Content) | (nm) | Note |
| n-type conductive layer 132 | 0.79 | ~1200 | Si doped |
| barrier layer 13B | 0.83 | 9 | Initial 18 nm thick, undoped |
| quantum well layer 13W | 0.77 | 3 | undoped |
| FB layer 13F | 0.83 | 1 | undoped |
| electron blocking layer 138 | 1.00 | 8 | undoped |
| 1st p-type doped layer 140 | 0.83 | 18 | Mg doped |
| composition gradient layer 150 | 0.95~0.79 | 144 | constant gradient |
| 2nd p-type doped layer 152 | 0.79 | 20 | Mg doped |

### 1-3. Enhancement of P-type Conductivity by Modified Polarization Doping

In order to demonstrate the enhancement of p-type conductivity by modified polarization doping, the inventors fabricated samples and conducted experimental verification. In particular, in order to confirm the effect of the improvement in the injection efficiency of the composition gradient layer 150, the inventors fabricated samples with a structure in which the UV transmittance of each layer responsible for p-type conduction and the UV reflectance of the electrode are not easily affected by the measured values, even though the electrical properties are clearly observed. In the following description, all of the sample operations are measured on the wafer without taking the final device mounting form (such as flip chip mounting).

### 1-3-1. Example 1

As an example sample 1 to confirm the effect of the improved p-type conduction characteristics in the present embodiment, a light-emitting device sample was fabricated on a wafer with the structure shown in FIGS. 1 and 2. The reflective electrode 160 was a composite layer of Ni/Au, with a thickness of 20 nm for the Ni. The structure of this reflective electrode 160 shows a low reflectance for the emission wavelength (230 nm). This allows the measurement of the emission performance without including the effect of the improvement in light extraction efficiency due to the electron blocking layer 138 to the second p-type doped layer 152, which are made transparent, and the reflective electrode 160 with its enhanced reflectivity. The reflective electrode 160 was 0.3 mm square.

### 1-3-2. Comparative Example Samples

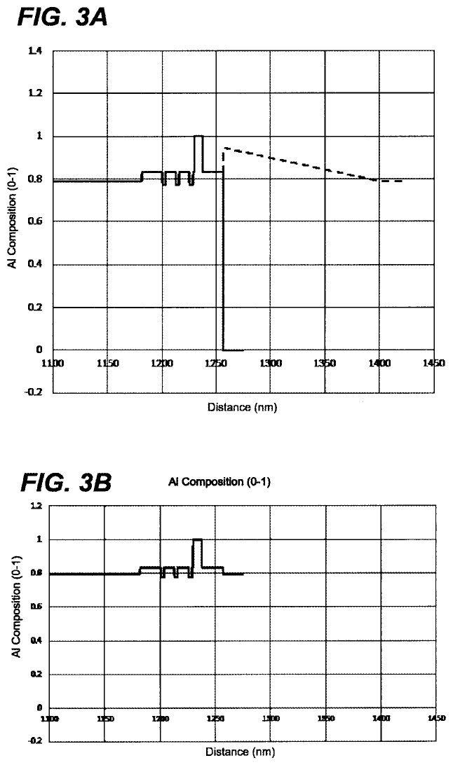

FIGS. 3A and 3B are graphs showing the Al composition ratio in comparative example samples that should be contrasted with the structure of the present embodiment. The structure of the substrate 110 to the first p-type doped layer 140 in the LED 100 and the structure of the reflective electrode 160 are the same for the comparative example samples 1 and 2 as for the example sample 1. In the comparative example sample 1, a p-type GaN contact layer (thickness 20 nm) is disposed in place of the composition gradient layer 150 and the second p-type doped layer 152 in the LED 100. In FIG. 3A, the Al composition ratio of the composition gradient layer 150 and the second p-type doped layer 152 of the example sample 1 is shown by a broken line for comparison. On the other hand, in the comparative example sample 2, a p-type AlGaN contact layer (Al composition ratio: 80%, thickness: 20 nm) with a flat composition gradient is disposed in place of the composition gradient layer 150 and the second p-type doped layer 152 in the LED 100. FIGS. 3A and 3B show the Al composition ratios in a manner that allows comparison with FIG. 2.

### 1-3-3. Control Experiment

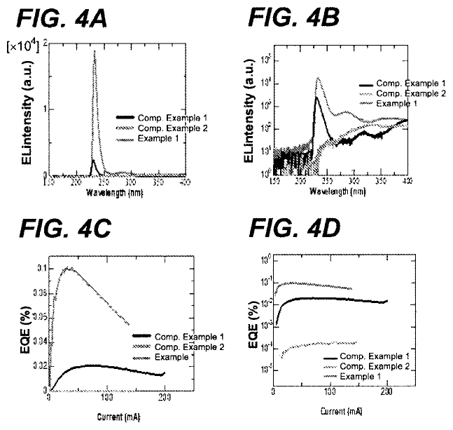

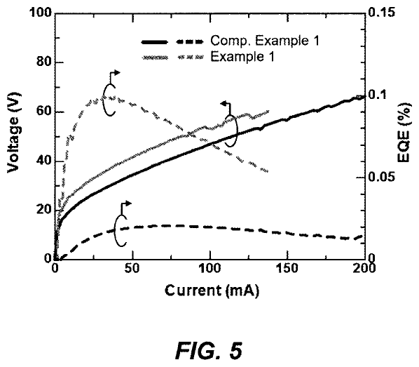

FIGS. 4A-4D show the experimental results of the light emission operation of the above-mentioned Example Sample 1 and Comparative Example Samples 1 and 2. All light emission operations were carried out at room temperature (300 K). The legend for the figures refers to Example Sample 1 as “Example 1.” FIGS. 4A and 4B show the EL emission intensity spectra on a linear scale and logarithmic scale, respectively. FIGS. 4C and 4D show the external quantum efficiency (EQE) on a linear scale and logarithmic scale, respectively. Comparative Example Sample 1, in which the layer directly in contact with the reflective electrode is a p-type GaN layer, performs the original operation of a light-emitting device in comparison with Comparative Example Sample 2, in which the layer is a p-type AlGaN layer. That is, as shown in FIGS. 4C and 4D, Comparative Example Sample 1 shows an external quantum efficiency value that can be called emission at a given voltage. In contrast, Comparative Example Sample 2 does not perform light emission. This means that either the ohmic contact to the reflective electrode is not working in the Comparative Example 2, or the p-type AlGaN layer does not provide electrical conduction. The Comparative Example 1 overcomes these problems by using a p-type GaN layer. However, its luminous efficiency is only 0.02%, which is not sufficient. In addition, only the comparative example 2 in FIGS. 4A and 4B was measured using a pulse operation with a duty period of sub-milliseconds and a duty ratio of 10%, while the example 1 and comparative example 1 were measured using a CW operation. In addition, the results in FIGS. 4C, 4D and 5 were all measured using pulse operation with a duty period of sub-milliseconds and a duty ratio of 10%.

In Example Sample 1, in contrast to Comparative Example Sample 1, a higher external quantum efficiency is achieved (FIGS. 4C and 4D) while maintaining the shape of the emission spectrum (FIGS. 4A and 4B) almost the same. That is, it was confirmed that the use of a composition gradient layer 150 in comparison to a p-type GaN layer improves the electrical injection efficiency, and can actually lead to an improvement in external quantum efficiency of around 10 times. In addition, comparing Example Sample 1, which uses a p-type AlGaN layer, with Comparison Sample 2, it can be said that if the p-type AlGaN layer does not perform polarization doping due to the composition gradient and only conducts impurities due to the Mg added as an impurity, the sample is fragile and easily destroyed. Furthermore, after the sample was broken, even when a voltage was applied, there was only a current leak. When comparing Example Sample 1 and Comparison Sample 2, Example Sample 1 can be understood as having a structure in which a composition gradient layer 150 is added immediately before the p-type AlGaN layer of Comparison Sample 2 (FIG. 3B). Therefore, the role of the composition gradient layer 150 in the LED 100 can be understood as a layer that gives layers responsible for p-type conduction a sufficient thickness to suppress current leakage, while still performing the necessary conductivity. The inventor's detailed consideration of this point will be discussed later (3-4).

FIG. 5 is a graph summarizing the current-voltage characteristics and light emission characteristics by contrasting the above-mentioned Example Sample 1 and Comparative Example Sample 1. It is important to note that there is not much difference in the current-voltage characteristics (left axis, horizontal axis) between Example Sample 1 and Comparative Example Sample 1. This means that the composition gradient layer 150 and the second p-type doped layer 152 in the Example Sample 1 have a similar effect on the electrical characteristics of the diode to the p-type GaN layer in the Comparative Example Sample 1, and the adverse effect on the electrical resistance value is not serious. Here, the p-type GaN layer has its own conductivity due to impurities, and it performs ohmic contact with the reflective electrode 160. In Example Sample 1, the electrical conductivity of the composition gradient layer 150 due to polarization doping is not much different from that of the p-type GaN layer, and when you take into account the thickness of the layer, it can be said that it shows sufficient conductivity. The performance of the ohmic contact can be said to be due to the effect of arranging the second p-type doped layer 152. The second p-type doped layer 152 is expected to have better UV transmittance than the p-type GaN in the comparative example sample 1, so it is useful in that it can contribute to improving the practical emission performance of the LED 100, which must take into account the light extraction efficiency.

### 1-4. Demonstration of Effective Use of Light by Reflective Electrodes

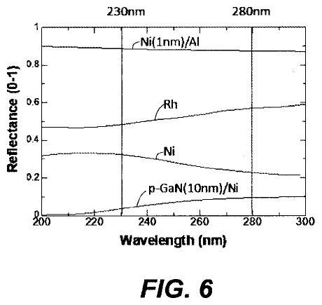

In order to confirm the effect of improving the light extraction efficiency of the LED element in the present embodiment, the UV reflective performance of the reflective electrode was confirmed by numerical calculation. FIG. 6 is a graph showing the reflectance spectrum in the wavelength range of 200 nm to 300 nm for several structures of reflective electrodes. The calculations were carried out using the simulation system (www.filmetricsinc.jp/reflectance-calculator) provided on the Filmetrics website. The conditions used to calculate the reflectance were based on assumptions that the reflective film being calculated for was formed on one side of an aluminum nitride (AlN) substrate, and that the light was incident perpendicularly on the reflective film from the AlN side. The parameters for each material, such as the complex refractive index, were automatically calculated using data provided on the Filmetrics website using this simulation system. The thicknesses of the layers other than those specified were set to the actual thicknesses used in the experiment, so that there would be no difference in the calculation results. As a result, the Ni (1 nm)/Al composite layer maintained a high reflectance over a wide wavelength range. For Ni, the reflectance actually increased at the short wavelength end. In contrast, Rh showed a slight decrease in reflectance as the wavelength became shorter. As the relative difference between Ni and Rh (both single layers) decreases with shorter wavelengths, it can be said that Rh single layers show relatively high reflectance on the long wavelength side of the calculated range, but their superiority decreases on the short wavelength side. In addition, even though the p-type GaN layer (p-GaN) is only 10 nm thick, its strong absorption results in a low reflectivity. In particular, the strength of the absorption on the short wavelength side was a serious problem when using reflection to increase the light extraction efficiency of the LED element.

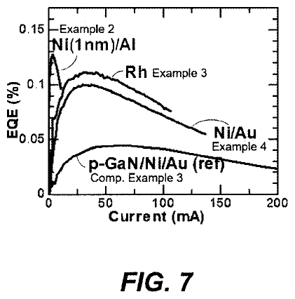

FIG. 7 is a graph of the external quantum efficiency when a sample with a modified structure of the reflective electrode is operated. All of the samples used the structure of the n-type conductive layer 132 to the second p-type doped layer 152 shown in FIGS. 1 and 2, and in addition, in the example samples 2, 3, and 4, the Ni (1 nm)/Al composite layer, Rh single layer, and Ni (20 nm)/Au composite layer electrodes were formed, respectively. In addition, in the Comparative Example Sample 3, a p-type GaN layer (10 nm)/Ni (20 nm)/Au composite layer was placed in the same way as the electrode. The electrode size of the reflective electrode 160 was 0.3 mm square, and the measurement was performed using a pulse operation with a duty period of sub-milliseconds and a duty ratio of 10% in a room temperature environment (300 K). The maximum external quantum efficiency was 0.045% for the comparative example sample 3, 0.13% for the example sample 2 that used the Ni/Al composite layer, 0.11% for the example sample 3 that used the Rh single layer, and 0.1% for the example sample 4 that used the Ni/Au composite layer. In addition, the example sample 2 had a large droop and was unable to sufficiently apply current.

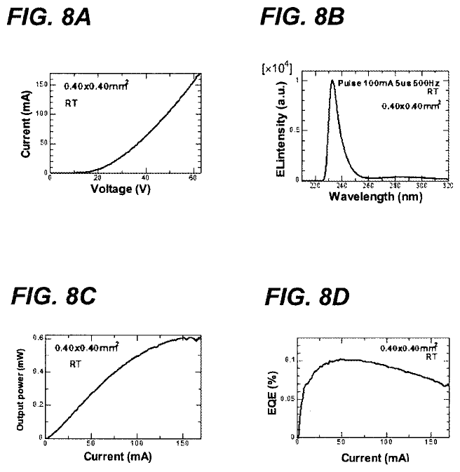

In Example Sample 3, measurements were taken on another sample that used the same Rh single layer and had a larger electrode size of 0.4 mm square for the reflective electrode 160. FIGS. 8A-8D show the current-voltage characteristics (FIG. 8A), emission spectrum (FIG. 8B), current-output power characteristics (FIG. 8C), and external quantum efficiency graph (FIG. 8D) when the sample was operated in the light-emitting mode. In this sample, emission of almost a single peak with a peak wavelength of 232 nm (FIG. 8B) was confirmed, and the output was 0.6 mW at maximum (FIG. 8C), and the external quantum efficiency was 0.11% (FIG. 8D). The conditions for the emission operation of the emission spectrum (FIG. 8B) were a room temperature environment, a duty period of 5 μs, and a repetition frequency of 500 Hz. The conditions for the current-voltage characteristics (FIG. 8A), current-output power performance (FIG. 8C) and the graph of external quantum efficiency (FIG. 8D) were measured under the following conditions: room temperature, pulse operation with a duty period of sub-milliseconds and a duty ratio of 10%. Although these measurements were taken before the chip was mounted, the output and external quantum efficiency are high, and have not been reported for LEDs in the wavelength range of around 230 nm. As shown here, good LED operation was confirmed by adopting the composition gradient layer 150. If the adoption of the composition gradient layer 150 makes it less likely for current leakage or destruction to occur compared to p-type AlGaN layers with a constant Al composition ratio, it will be easier to increase the electrode size of the reflective electrode 160, which is advantageous for achieving high output.

### 1-5. Transmittance

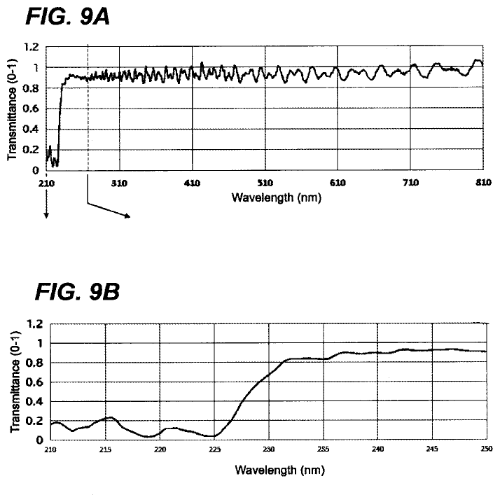

FIGS. 9A and 9B are graphs showing the transmittance spectrum of a sample in the structure of LED 100 before the nitride semiconductor portion is formed and electrodes are formed. These graphs show that sufficient light transmittance is obtained from the visible range to the deep ultraviolet range in the semiconductor structure shown in FIG. 2. In other words, this shows that the absorption edge given by the lower limit of the Al composition ratio is shortened sufficiently. In order to increase the light extraction efficiency in combination with the reflection effect of the reflective electrode 160 in the application of LED 100, the minimum value of the Al composition ratio in the composition gradient layer 150 is set so that the absorption edge at the minimum Al composition ratio is shorter than the emission peak wavelength of the emission layer 134. FIGS. 9A and 9B show examples of transmittance in an actual sample in which the minimum Al composition ratio in the composition gradient layer 150 is 0.8, and show that the LED 100 has sufficient UV transmittance when the emission wavelength is 230 nm or more.

### 2. Embodiment of a Laser Diode

The UV light-emitting device of the present embodiment can also be operated as a laser diode (LD). In a laser diode, the emitted UV is confined over the thickness direction of the element, and in at least one direction perpendicular to this, the emitted UV is reflected by the end or external resonator reflecting surface to induce stimulated emission and amplify the UV. The present embodiment can contribute to a decrease in the lasing threshold, higher output power, and higher operating temperature of the LD by increasing the p-type conductivity and performing or maintaining population inversion in the emission layer (active layer).

### 2-1. Structure of LD in the Present Embodiment

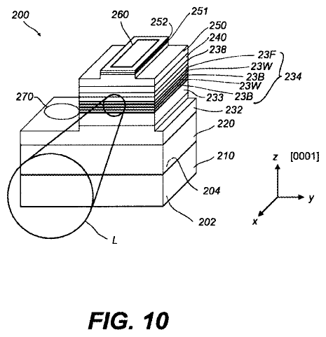

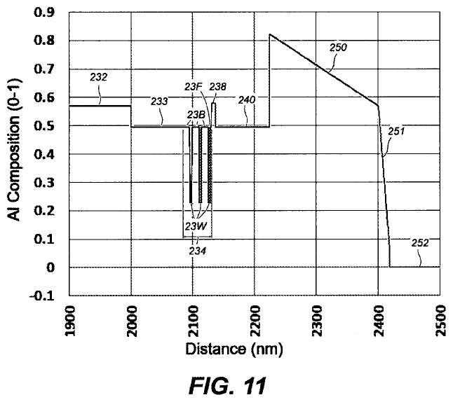

FIG. 10 is a schematic diagram showing the main components of the LD 200 of a present embodiment. FIG. 11 is a graph showing the Al composition ratio at each position in the thickness direction of an example of the structure of the LD 200 of a present embodiment (design wavelength: 280 nm to 290 nm), and the range from the n-type cladding layer 232 to the p-type GaN layer 252 is shown. The symbols used in FIG. 10 are used in each part of the graph in FIG. 11. The laser diode uses a low refractive index cladding and a high refractive index core (waveguide, waveguide) to confine the emitted UV over the thickness direction (z-direction in FIG. 10), and the emitted UV is amplified while maintaining coherence by feeding back at least one direction perpendicular to the thickness (a direction included in the xy plane) through the end face or external cavity. In AlGaN-based crystals, the refractive index decreases as the Al composition ratio increases. This property is used to confine UV over the thickness direction, and the Al composition ratio is set to be larger in the layer that becomes the cladding by sandwiching the core over the thickness direction than in the part that becomes the core. In the typical structure of LD 200 shown in FIG. 10, the n-type cladding layer 232 has a higher Al composition ratio than the n-side waveguide (WG) layer 233, as compared to the LED 100 shown in FIG. 1. In addition, although not shown in FIG. 10, elements for operation, such as a protective layer of SiO2 and a pad electrode for conducting from the outside to the electrode, are also added as appropriate.

In the LD 200, a buffer layer 220 is epitaxially grown on one side 204 of a substrate 210, which is a flat c-plane α-Al₂O₃ single crystal (sapphire), using a material such as AlN crystals. From the side of the buffer layer 220, the n-type cladding layer 232, n-side waveguide (WG) layer 233, emission layer (active layer) 234, electron blocking layer 238, p-side waveguide (WG) layer 240, composition gradient layer 250, additional composition gradient layer 251, p-type GaN layer 252, and electrode 260, which acts as the second electrode, are stacked in this order. The n-side WG layer 233 to p-side WG layer 240 forms the core, and the n-type cladding layer 232 and composition gradient layer 250 form the cladding, and a light confinement structure in the thickness direction is realized. The refractive index of the composition gradient layer 250 is high on the p-side WG layer 240 side, and the refractive index decreases stepwise at the interface with the p-side WG layer 240, so the composition gradient layer 250 acts as a cladding layer. The radiation L is emitted from one end face parallel to the xy plane. The p-type GaN layer 252 functions as the second p-type doped layer.

The material of the n-type cladding layer 232 and the additional composition gradient layer 251 is typically AlGaN or InAlGaN, or a composition to which a trace element (impurity, Si for n-type, Mg for p-type) is added as necessary. The p-type GaN layer 252 is made by adding Mg to GaN.

Specifically, silicon is added as an impurity to the n-type cladding layer 232 to make it n-type. In contrast, the n-side WG layer 233 is an undoped layer that is designed to prevent scattering due to impurities. The active layer 234 is a layer in which quantum levels for emission are formed, and it is made up of a stack of a barrier layer 23B and a quantum well layer 23W, with the final barrier layer referred to as the final barrier (FB) layer 23F. In comparison with the n-side WG layer 233, the barrier layer 23B has the same Al composition ratio, whereas the quantum well layer 23W has a reduced Al composition ratio to form the quantum well. The thickness of the barrier layer 23B is determined in accordance with the emission wavelength. The FB layer 23F has the same Al composition ratio as the n-side WG layer 233, and its thickness is determined so as not to affect the energy value of the nearest barrier layer 23B. The electron blocking layer 238 acts to prevent electron overflow.

The electron blocking layer 238 has a higher Al composition ratio than the front and back FB layers 23F and the p-side WG layer 240, and as a result, the refractive index is reduced. However, by configuring the electron blocking layer 238 to be thin, it is possible to suppress electron overflow while sufficiently reducing the effect on the light propagation mode in the n-side WG layer 233 to p-side WG layer 240, which functions as the core.

Mg is added as an impurity dopant to the p-side WG layer 240 and the p-type GaN layer 252. In the p-side WG layer 240, it is preferable to have fewer impurities that could act as scattering sources in order to suppress the conduction loss of light. In fact, in the disclosures of non-Patent Documents 3 and 4, no impurities are doped in the layers at this position. In contrast, in the present embodiment, LD 200, impurities are doped into the p-side WG layer 240, and the concentration is set appropriately. This is because the priority is to achieve population inversion by increasing the carrier injection efficiency, taking into account the entire lasing operation. If the p-type GaN layer 252 is sufficiently doped with acceptor impurities, it will be easier to perform ohmic contact.

The present inventors have found that, in a structure that employs a composition gradient layer 250, an electron blocking layer 238, and a p-side WG layer 240, the efficiency of electron injection is improved by approximately 10 times compared to a structure that employs a composition gradient layer but does not have an electron blocking layer near the emission layer and does not dope impurities into the WG layer. Therefore, the inventors have found that it is advantageous for electrical operation to combine a composition gradient layer that induces holes, an electron blocking layer 238 that is located close to the quantum well layer 23W, where optical transitions occur due to recombination, and a p-type conduction layer that performs p-type conduction by impurity doping, such as the p-side WG layer 240.

The impurity concentration of the additional composition gradient layer 251 and the p-type GaN layer 252 is determined from the perspective of the electrical resistance value between the electrodes 260. If the composition gradient layer 250, which acts as a cladding, is formed to a sufficient thickness, the scattering and other optical effects caused by impurities in the additional composition gradient layer 251 and p-type GaN layer 252 will not be a factor in performance degradation. In addition, the reflectivity of the electrode 260 is not a problem in the LD 200. These points should be contrasted with the fact that the second p-type doped layer 152 of the LED 100 (FIG. 1) requires light transmissivity, and the reflective electrode 160 requires reflectivity.

The specific structure of each semiconductor layer in the example of the LD 200 structure shown in FIG. 11 is as follows.

TABLE 2

| | Al Composition | Thickness | |
|---|---|---|---|
| Layer (with ref numeral in FIG. 11) | Ratio (Content) | (nm) | Note |
| n-type cladding layer 232 | 0.57 | ~2000 | Si doped |
| n-side WG layer 233 | 0.50 | 84 | undoped |
| barrier layer 23B | 0.50 | 11 | undoped |
| quantum well layer 23W | 0.23 | 3 | undoped |
| FB layer 23F | 0.50 | 1.2 | undoped |
| electron blocking layer 238 | 0.58 | 7 | undoped |
| p-side WG layer 240 | 0.50 | 88 | Mg doped |
| composition gradient layer 250 | 0.82~0.57 | 175 | constant gradient |
| additional composition gradient layer 251 | 0.57~0.07 | 18 | constant gradient |
| p-type GaN Layer 252 | 0.00 | 80 | Mg doped |

### 2-2. Impurity Densities in P-side WG Layer 240

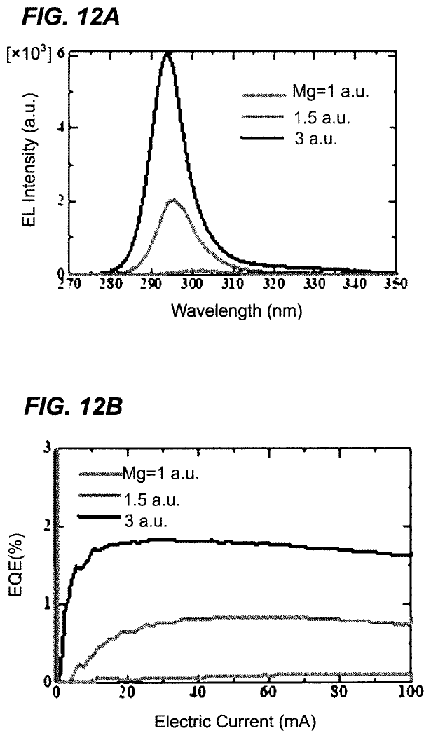

FIGS. 12A and 12B show the results of performance verification when samples with a structure similar to that of LD 200 were operated as LEDs, with the impurity density in the p-side WG layer 240 changed. EL emission spectra (FIG. 12A) in CW operation (20 mA) and external quantum efficiency (FIG. 12B) calculated from the emission intensity in pulse operation (electrode size: 0.2 mm square) at room temperature (300 K). These samples were fabricated under conditions that were assumed to be suitable for lasing operation at a wavelength of 280 nm to 290 nm. In order to confirm the effect of the impurity concentration in the p-side WG layer 240, three samples were prepared with impurity concentrations that were 1×, 1.5×, and 3× the standard freely chosen unit (a.u.). In the case of LD 200, UV is extracted by moving back and forth along the x-axis shown in FIG. 10, and almost no UV penetrates the n-type cladding layer 232 and composition gradient layer 250, which function as the cladding. In contrast, the sample whose performance was confirmed has the structure for LD 200 and is operating as an LED. Therefore, when UV is emitted from the emission layer 234, it travels in the positive and negative directions of the z-axis as shown in FIG. 1. The component in the negative direction of the z-axis travels towards the electrode 260, and is absorbed to some extent by the additional composition gradient layer 251, p-type GaN layer 252, and electrode 260 in the process. Due to this difference in operation, the EL emission spectra and external quantum efficiency in FIGS. 12A and 12B do not reflect all of the performance required for operation as a laser diode. However, as long as the samples are only compared relative to each other, it is possible to evaluate how the differences in structure between the samples are related to the electrical characteristics that lead to emission.

As shown in FIGS. 12A and 12B, increasing the impurity concentration in the p-side WG layer 240 shifted the peak wavelength of the emission to the shorter wavelength side, and the emission intensity was also significantly enhanced. The peak wavelength of the actual EL emission was 292 nm, which had the strongest intensity and was shifted to the shorter wavelength side (FIG. 12A). In addition, the injection efficiency increased from 0.2% to 1.8%, a nine-fold increase, depending on the Mg impurity concentration in the p-side WG layer 240 (FIG. 12B). From these results, it can be said that at least the Mg impurity concentration in the p-side WG layer 240 has a direct effect on LED operation. This significant improvement in the efficiency of current injection suggests that population inversion is more easily formed, and indicates the superiority of the structure of LD 200, which combines the electron blocking layer 238, the p-side WG layer 240, and the composition gradient layer 250, in terms of electrical operation by adding Mg as an impurity to the p-side WG layer 240. At this stage, the present inventors have not confirmed lasing operation using the LD 200 structure. However, the results suggest that the structure of adding Mg as an impurity to the p-side WG layer 240 could be an extremely effective means of achieving population inversion when lasing is performed.

In addition, the results of FIGS. 12A and 12B also demonstrate that the addition of Mg as an impurity to the first p-type doped layer 140 has a favorable effect on the efficiency of current injection in the LED 100, which has a structure similar to that of the LD 200, in which the electron blocking layer 138, the first p-type doped layer 140, and the composition gradient layer 150 have the same structure as those of the LD 200.

### 3. Details of Components and Examples of Variations

The various components of the UV light-emitting device in the present embodiment described above include various innovations. In addition, the UV light-emitting device in the present embodiment can be implemented in various variations.

### 3-1. Second Doped Layer

The Al composition ratio in the second p-type doped layer 152 and p-type GaN layer 252 of the LED 100 and LD 200 is approximately equal to the Al composition ratio on the closest side of the composition gradient layer 150 and the additional composition gradient layer 251, such that the difference between them is within 0.3, preferably within 0.2, and even more preferably within 0.1. The reason for this is firstly to suppress the adverse effects that charge accumulation at the interface due to the step in the Al composition ratio can cause, and secondly to make the Al composition ratio as small as possible for ohmic contact with the reflective electrode 160 and electrode 260 respectively. In the LD200, the additional composition gradient layer 251, which has a gradient in the Al composition ratio, is also part of the composition gradient layer.

### 3-2. Electron Blocking Layer

The electron blocking layers 138 and 238 of the LED 100 and LD 200 do not necessarily have to be single layers. These electron blocking layers can also be two or more high Al composition ratio AlGaN layers (including AlN layers) sandwiched by a low Al composition ratio intermediate layer. In another typical example, the electron blocking layer can also be a layer in which the Al composition ratio is alternatingly increased and decreased to produce a multiple quantum barrier (MQB) (multiple quantum barrier layer) or in which the alternating cycle of the layer is gradually increased or decreased (chirped). The content of the disclosure in the Patent Document 1 disclosed by the present inventors shall be deemed to be part of the present application by incorporating it in its entirety by reference. The optimization of the electron blocking layers 138 and 238 is carried out by the Al composition ratio that determines the height of the conduction band edge and the thickness of the layer itself in the case of a single layer. In the case of two or more layers, in addition to the Al composition ratio and thickness of each individual layer, the Al composition ratio and thickness of the intermediate layer placed between each layer are also adjusted. In addition, the distance of the electron blocking layers 138 and 238 from the final quantum well layers 13W and 23W is also adjusted according to the thickness of the FB layers 13F and 23F.

When optimizing electron block layers 138 and 238 in response to the emission wavelength, if the emission wavelength is a short wavelength, for example 230 nm, the Al composition ratio of electron block layers 138 and 238, which is necessary for blocking electrons, can be increased, and it can even be replaced with AlN. The thicker the electron blocking layers 138 and 238, the better for blocking electrons. In the electron blocking layer 238 of the LD 200, the position where it is arranged is the core of the waveguide, and there is a concern that increasing the Al composition ratio will lower the refractive index. However, by reducing the thickness of the electron blocking layer 238, the negative effects on the light wave can be suppressed.

### 3-3. Optimization of the P-Type Conducting Layer

The p-type conducting layer in the LED 100 and LD 200 includes the first p-type doped layer 140, the p-side WG layer 240, and the composition gradient layers 150 and 250. The thickness of the first p-type doped layer 140 in the LED 100 is responsible for generating a certain concentration of carriers (holes) and producing a certain amount of those carriers. The thickness of the p-side WG layer 240 in LD 200 is responsible for these roles, as well as for adjusting the position of the quantum well layer 23W of the active layer 234 to be in a position where the amplitude of the optical electric field in which the light is confined during lasing is strong. In addition, as shown in FIGS. 12A and 12B, the impurity concentration in the first p-type doped layer 140 and the p-side WG layer 240 has a direct effect on the p-type conduction characteristics.

In addition, the layers that are responsible for p-type conduction, including composition gradient layers 150 and 250, can be optimized from various perspectives. First, the distribution of the Al composition ratio can be changed to improve p-type conductivity. The change in the Al composition ratio in the composition gradient layers 150 and 250 depending on the position over the thickness direction can be made in various ways, such as a continuous change, a monotonous change, a discontinuous change, or a step-like change, and it is also possible to combine multiple sets of these changes. In the composition gradient layers 150 and 250 shown in FIGS. 2 and 11, the Al composition ratio changes in a manner that has a constant gradient depending on the position, and in this case, the effect of polarization doping is constant regardless of the position over the thickness direction.

The greater the gradient of the Al composition ratio in the composition gradient layers 150 and 250, the stronger the effect of polarization doping. According to the simulations by the present inventor, even if the composition gradient is only a linear decrease from 1.0 to 0.5 in Al composition ratio over a thickness of 300 nm, the carrier concentration of holes is approximately 10¹⁸ cm⁻³ even without doping. This is a sufficiently high value that greatly exceeds the value (approximately 3×10¹⁷ cm⁻³) required for the operation of LEDs and LDs. Thus, it can be said that a composition gradient in which the Al composition ratio decreases by about 0.5 per 300 nm contributes to improving the carrier injection efficiency.

The thicknesses of the composition gradient layers 150 and 250 serve to suppress current leakage. This point will be discussed later (3-4). In addition, the composition gradient layer 250 also has the effect of a cladding layer that further confines light.

The composition distribution of the Al composition ratio in the composition gradient layers 150 and 250 is configured to decrease in the direction of the electron flow (rightward on the horizontal axis) in FIGS. 2 and 12A and 12B. In this way, holes are induced in the composition gradient layers 150 and 250 in a structure in which Ga or Al of the AlGaN is grown in the [0001] direction on the Ga-face, where the Ga or Al is exposed on the surface, and the direction of electron flow is in the [0001] direction. In a structure where the material is grown in the [000-1] direction on the N-face, holes can be induced in the composition gradient layer by a composition distribution that increases the Al composition ratio in the direction of [000-1].

Furthermore, the carrier generation effect of polarization doping can be expected even if the composition gradient layers 150 and 250 are undoped. However, even if the composition gradient layers 150 and 250 are doped with impurities, the effect of polarization doping can be expected in addition to the carrier generation effect due to the activation of impurities. Therefore, in the composition gradient layers 150 and 250, both the effect of polarization doping due to the distribution of the Al composition ratio, i.e., the effect due to the change in the Al composition ratio over the thickness direction, i.e., the distribution, and the effect due to the impurity concentration depending on whether or not the composition gradient layers 150 and 250 are doped with impurities themselves, affect the p-type conduction performance. By optimizing these factors, it is possible to expect improvements in the light-emitting efficiency of UV light-emitting devices.

The transmission property for the light emission wavelengths shown in FIGS. 9A and 9B is particularly advantageous when the device is used as a light emitting diode. This is because the light extraction efficiency is increased by utilizing the UV light reflected by the reflective electrode. On the other hand, the situation is different when the device is used as a laser diode. When amplifying light by inducing stimulated emission, light is confined over the thickness direction to the core by the cladding. The photoelectric field hardly penetrates the cladding, and whether or not the UV is reflected by the reflective electrode is irrelevant to the operation. Therefore, it is possible to select materials that focus on electrical performance only outside the cladding, and it is also possible to adopt materials that strongly absorb the emission wavelength, such as p-type GaN layer 252.

### 3-4. Leakage Suppression Effect of the Undoped Composition Gradient Layer

Example Sample 1, which has the structure of LED 100 in FIG. 2, can also be considered to have a structure in which a composition gradient layer 150 is added immediately adjacent to the p-type AlGaN layer of Comparative Example Sample 2 (FIG. 3B). As described above, the function of the composition gradient layer 150 in the LED 100 can be understood as a layer that gives the p-type conduction layer the thickness required to suppress current leakage, while also performing the necessary conductivity. This is a finding that the inventors derived from the fact that there was less damage in the comparison between the Example Sample 1 and the Comparative Example Sample 2. The present inventors suspect that columnar defects during crystal growth are involved in the action of this composition gradient layer.

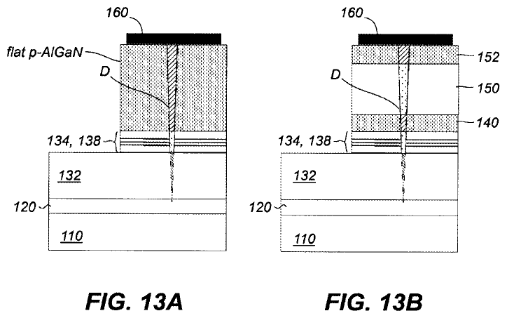

FIGS. 13A and 13B are explanatory diagrams to illustrate the presumed effects of the composition gradient layer 150 in the present embodiment. FIGS. 13A and 13B show the main parts of a comparative example LED in which a Mg-doped AlGaN layer with a constant Al composition ratio is used instead of the composition gradient layer 150, as in Comparative Example Sample 2, and an example LED structure of LED 100, which has a composition gradient layer 150 that is not Mg-doped, as in Example Sample 1. In actual UV light-emitting devices, it is not always possible to perform ideal crystal growth. When the inventors observed the surface of the buffer layer on the substrate (the surface at the step of forming the buffer layer 120 on the substrate 110), multiple hillocks were formed at a certain density. When the buffer layer with such hillocks is followed by crystal growth of the n-type conductive layer 132, the emission layer 134, the electron blocking layer 138, etc., columnar defects can be induced in the crystal. Such columnar defects typically extend in the thickness direction while spreading in the in-plane direction as a result of epitaxial growth, and they can penetrate the n-type conductive layer 134 to the electron blocking layer 138 and reach the p-type conductive layer.

The concentration of impurities can be locally affected at the location of columnar defects. This can occur in both n-type and p-type regions, but at the location of columnar defect D, there is a possibility of having a higher Mg concentration than the surrounding area. In the comparative example LED structure shown in FIG. 13A, in which a Mg-doped AlGaN layer with a certain Al composition ratio is used, such a region of high Mg concentration forms in the range of columnar defect D and penetrates the p-type Mg-doped AlGaN layer over the thickness direction. If a current is applied to the comparative example LED via the reflective metal electrode 160 in this state, the electric field will be concentrated in the emission layer 134 at the location of the columnar defect D, and the part of the emission layer 134 at the columnar defect D will change into a current leakage path. Therefore, in the comparative example LED, columnar defect D produces a short cut path between n and p, and once the fabricated light-emitting device is driven, it irreversibly transforms into a situation where it does not emit light and is destroyed. In this way, columnar defects can induce current leak paths.

In contrast, if the composition gradient layer 150 of the LED shown in FIG. 13B is not doped with Mg as an impurity, even if columnar defects D are formed, carrier activation in the columnar defect region is prevented, and the current leakage path is fragmented. Of course, in the first p-type doped layer 140 and the second p-type doped layer 152, which sandwich the composition gradient layer 150, Mg is doped as an impurity, and there is a possibility of non-uniformity in the impurity concentration in each layer. However, the carrier density of the composition gradient layer 150 is determined by the composition gradient and is unrelated to the planar distribution of impurity concentration that can occur in the layers on either side of it. By adopting a composition gradient layer that uses only PD carriers, even if the layers on either side are affected by columnar defects, the effect is also broken up by the composition gradient layer 150. As a result, the adverse effect of turning the columnar defect D in the emission layer 134 into a leakage path can also be prevented. Therefore, the undoped composition gradient layer 150 may not only promote hole current, but also break up current leakage paths.

The inventors believe that if a composition gradient layer 150 that employs carrier generation using only PD, i.e., an undoped composition gradient layer, is used, it will be difficult for columnar defects D to lead to leakage. Furthermore, although it is assumed that the carrier concentration is probably higher in the local region of the columnar defect in the Mg-doped AlGaN layer than in the surrounding bulk region, the exact carrier type and carrier concentration are unclear. However, the inventor's estimation as explained with reference to FIGS. 13A and 13B is consistent with the experimental fact in the comparison of Example Sample 1 and Comparative Sample 2.

Therefore, a structure in which impurities are not doped into the composition gradient layer could be particularly useful in UV light-emitting devices that use heterogeneous substrates, which are prone to forming columnar defects. Heterogeneous substrates refer to substrates made of a different crystal system to that of the AlGaN or InAlGaN crystals that make up the UV light-emitting device. As a typical example, if an AlN substrate or a GaN substrate is used for the crystal growth of an AlGaN-based or InAlGaN-based UV light-emitting device, then it is not a heterogeneous substrate, but if a sapphire substrate is used, then it is a heterogeneous substrate. The explanation in this section can also be applied to the operation of LDs grown on heterogeneous substrates and to the case where an undoped composition gradient layer 250 is used. Non-Patent Document 6 also discloses that even when a PD is used with an AlN single crystal substrate, a structure attributable to a crystal defect called a HPH (hexagonal-pyramid-shaped hillock) may occur, and that current leakage is unavoidable in such a structure. The inventors believe that it is difficult to reduce the frequency of the appearance of hillocks and columnar defects caused by them even when using a high-quality buffer layer formed on an AlN single crystal substrate, which cannot be considered a heterogeneous substrate.

When an undoped composition gradient layer is adopted for the purpose of suppressing current leakage, the thickness of the layer can be designed to be suitable for breaking up the effects of columnar defects, as well as having the necessary gradient in the Al composition ratio. Specifically, the composition gradient layer of the undoped layer is preferably designed as an insulating cap layer by forming it to cover the protrusions or pits that can induce columnar defects that can occur in the AlGaN or InAlGaN crystal of the UV light-emitting device. The phrase “covering the protrusions or pits” means covering both the top or bottom surface of the protrusions or pits and the side surface of the protrusions or pits, i.e., the flat surface that creates the step, which is not parallel to the flat surface, when a protrusion or pit that can cause a columnar defect is present on the flat surface around the composition gradient layer 150 just before it is formed, i.e., at the time the first p-type doped layer 140 is formed. In such a case, the scale correlation between the height of the protrusion or pit and the thickness of the undoped composition gradient layer is not necessarily limited. If the composition gradient layer of the undoped material covers this protrusion or pit, the composition gradient layer can exert the effect of breaking up the current leakage described above. In other words, the composition gradient layer of the undoped material can perform the function of an insulating cap layer.

In addition, in terms of the effect of suppressing current leakage, the lower limit of the Al composition ratio of the composition gradient layer 150 can be taken into account in the design of the undoped composition gradient layers 150 and 250, as described above, in accordance with the requirements for UV transparency.

### 3-5. InAlGaN-Based Crystals

The structure comprising an electron blocking layer, a p-type doped layer, and a composition gradient layer, which is adopted in the present embodiment, is also applicable to structures using InAlGaN crystals as well as AlGaN crystals. In this case, the Al composition ratio in the composition gradient layer indicates the fraction of AlN in the InAlGaN crystal.

### 3-6. Wavelength Range

The technical concept of the present embodiment can also be applied to LEDs and LDs that have a principal wavelength of light in the deep ultraviolet range of 210 nm to 360 nm, beyond the specific wavelength range for which operation was confirmed by samples. The longer the principal wavelength, the easier it is to operate, and the shorter the principal wavelength, the more necessary it becomes to increase the Al composition ratio of the AlGaN or InAlGaN crystal, and it becomes more difficult to achieve p-type conductivity using other methods. For this reason, the lower limit of the principal wavelength for LED operation is preferably 220 nm. In addition, the upper limit of the principal wavelength for LED operation is preferably 300 nm, more preferably 280 nm, even more preferably 250 nm, and even more preferably 240 nm. The inventors of this application have also actually fabricated and confirmed the operation of a sample of the structure of LED 100 (FIGS. 1 and 2) (not shown), even for an LED designed to emit light at 280 nm. Although the performance of this sample was not found to be superior to that of a comparative sample that employed a flat p-type AlGaN contact layer, it was found to be superior in that its breakdown was significantly suppressed. In addition, the lower limit of the principal wavelength in the operation of the LD is preferably 240 nm, and more preferably 250 nm. In addition, the upper limit of the principal wavelength in the operation of the LD is preferably 360 nm, more preferably 300 nm, even more preferably 250 nm, and even more preferably 230 nm. In the present embodiment, any combination of these upper and lower limits can be used to specify the wavelength range for a preferred UV light-emitting device.

### 3-7. Manufacturing Method

The manufacturing method for the light-emitting device that can be adopted for the present embodiment is not particularly limited. An example crystal growth method is as follows: after preparing a c-plane sapphire wafer, etc., the wafer is pre-treated, and then the wafer is introduced into an epitaxial growth device to produce a layered structure of AlGaN or InAlGaN crystals by means of epitaxial growth. The crystal growth method can employ, for example, the MOVPE method or the MBE (Molecular Beam Epitaxy) method. In the MOVPE method, it is preferable to use trimethylaluminum (TMAI) as the raw material gas for aluminum. In addition, it is preferable to use trimethylgallium (TMGa) as the raw material gas for Ga. It is preferable to use NH₃ as the raw material gas for N. It is preferable to use tetraethylsilane (TESi) as the raw material gas for Si, which is an impurity that imparts n-type conductivity. Bis-cyclopentadienyl magnesium (Cp₂Mg) is preferable as the raw material gas for Mg, which is an impurity that contributes to p-type conductivity. For the carrier gas for each raw material gas, for example, H₂ gas is preferable. There are no particular restrictions on the raw material gases used, and for example, triethylgallium (TEGa) can be used as the raw material gas for Ga, hydrazine derivatives can be used as the raw material gas for N, and monosilane (SiH₄) can be used as the raw material gas for Si. The conditions for crystal growth can be set as appropriate, including the substrate temperature for each layer, the V/III ratio, the supply amount of each raw material gas, and the growth pressure. Details of crystal growth are disclosed in, for example, Patent Document 1.

In addition, any method used by a person skilled in the art may be employed for the formation of metal electrodes, the formation of electrodes, the shaping of semiconductor laminates, and the formation of protective films and reflective end faces in LDs.

### 4. Additional Verification

The results of additional experimental verification to supplement the respective embodiments of the light-emitting diode and laser diode described above for the present disclosure are described below.

### 4-1. Supplement to the Embodiment of the Light-Emitting Diode

In order to further improve the performance of the light-emitting diode described in the embodiment of the light-emitting diode (Section 1 above), several additional experimental verifications were conducted: The first is optimization of the quantum well layer structure (4-1-1), the second is improvement of the template and n-type conductive layer (-2), the third involves the introduction of a p-GaN contact layer (-3), the fourth is about increasing the number of quantum well layers (-4), and the fifth is adjustment of modulated doping and composition gradient.

### 4-1-1. Optimization of Quantum Well Layer Structure

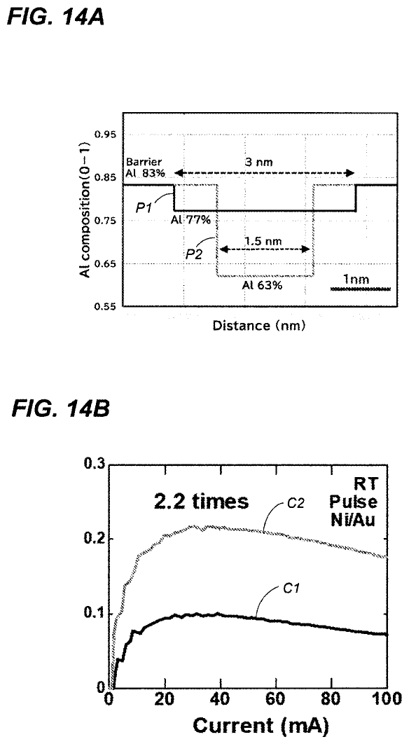

In the structure of LED 100 in FIG. 2, the thickness of the quantum well layer 13W was 3 nm and the Al composition ratio was 0.77 (see Table 1). Further investigation revealed that good performance could be achieved by making the quantum well layer 13W thinner and reducing the potential exerted on the electrons (making the quantum well deeper). Specifically, the quantum well layer 13W was made 1.5 nm thick, with an Al composition ratio of 0.63. FIGS. 14A and 14B are illustrations showing the profile of the Al composition ratio in one of the quantum well layers (FIG. 14A) and a graph showing the current characteristics of the external quantum efficiency measured from each sample structure (FIG. 14B). In each figure, the structure of LED 100 (profile P1, curve C1) is contrasted with the structure of the thin and deep structure (profile P2, curve C2). As shown in FIG. 14B, it has been confirmed that the external quantum efficiency is improved by 2.2 times while maintaining the emission spectrum in a similar manner by thinning and deepening the quantum well layer 13W.

The reason for this is explained from the perspective of both the improvement of the internal quantum efficiency (IQE) and the improvement of the TE mode ratio in radiation. The improvement in IQE is mainly due to the relaxation of the quantum confined Stark effect (QCSE). QCSE is attributable to the fact that the conduction band edge potential and the valence band edge potential at the position of the quantum well have a slope due to the influence of the spontaneous dipole caused by the external electric field and the polarity of the crystal. This slope causes the overlap integral between the wave functions of the electron and hole pairs that should recombine through optical transitions in the quantum well to become smaller than it would be without the slope. The degree of reduction in the overlap integral depends on the thickness of the quantum well layer, and the use of a thinner quantum well layer is a measure to alleviate this. In addition, in a thin quantum well, the energy difference between the levels in which electrons and holes are confined increases, but this can be dealt with by making the potential difference in the quantum well part smaller, that is, by making the quantum well deeper.

The improvement in the TE mode ratio is also attributable to the fact that, in the case of short wavelengths in UV LEDs such as LED 100, the polarization state of the emitted UV light differs depending on whether it is in TM (transverse magnetic) mode or TE (transverse electric) mode, and this affects the light extraction efficiency from the LED 100 element. TM-mode UV light has a profile that radiates in the in-plane direction of the layered structure of the quantum well layer 13W, barrier layer 13B, etc., and so it is scattered or absorbed as it propagates through the interior of the LED, which has a size on the order of millimeters. For this reason, TM-mode UV light is easily attenuated before being emitted outside. On the other hand, TE-mode UV light has a profile in which the radiation direction is oriented along the thickness direction of the layered structure, and it is easy to emit directly outside or to extract it from the LED 100 to the outside with the help of the reflective electrode 160, for example.

### 4-1-2. Improvements to the AlN Template and N-Type Conductive Layer

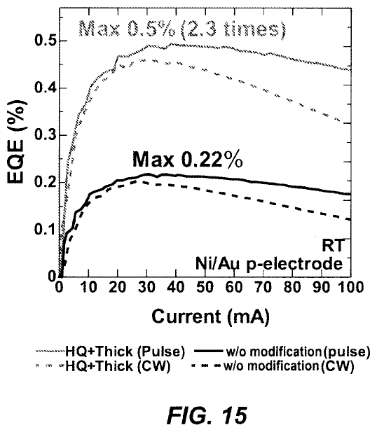

The inventors confirmed that good performance could be achieved in the LED 100 by improving the substrate 110, buffer layer 120 (hereinafter collectively referred to as the AlN template) and n-type conductive layer 132. Specifically, in the buffer layer 120 deposition conditions, the ammonia pulse supply AlN crystal growth method was introduced from the initial nitride AlN crystal growth method on the sapphire surface. Specifically, in Sections 3-4, the effect of the composition gradient layer 150 on suppressing leakage was described with reference to FIGS. 13A and 13B. The method used was the initial nitridation of sapphire surface AlN crystal growth method, which can produce relatively high-quality AlN templates with only simple adjustments using a small number of adjustment parameters (see Non-Patent Document 9). Here, the inventors focused on a different means of solving the leakage problem, namely, improving the crystal quality of the AlN template, and introduced the ammonia pulse supply AlN crystal growth method (see Patent Document 1). The ammonia pulse supply AlN crystal growth method requires precise tuning, but it can produce AlN templates with sufficiently reduced threading dislocation density. When the ammonia pulse supply AlN crystal growth method, which had actually been precisely tuned under the buffer layer 120 film deposition conditions, was adopted, it was found that the formation of columnar defects in the buffer layer 120 could be sufficiently suppressed. Furthermore, the thickness of the n-type conductive layer 132 was increased by 15% from that of LED 100 (approximately 1200 nm, Table 1), resulting in a structure in which the crystal defects that can occur in the AlN template have less impact on the performance and quality of LED 100. As a result of improving the crystal quality of the AlN template and increasing the thickness of the n-type conductive layer 132, the efficiency was 2.3 times higher than that of the LED 100 with the structure shown in Table 1, and an external quantum efficiency (EQE) of 0.5% was achieved with light emission having a peak wavelength of 232 nm. FIG. 15 is a graph showing the actual measured external quantum efficiency of samples before and after the improvement of the AlN template and n-type conductive layer. The reflector electrode 160 was made of Ni/Au. To the best of the inventor's knowledge, there is no previous example of a light emission efficiency that achieves a maximum external quantum efficiency of 0.5% at 232 nm. The sample used to obtain the measurement values in FIG. 15 was made using the optimization of the quantum well layer structure (Section 4-1-1).

### 4-1-3. Introduction of P-GaN Contact Layer

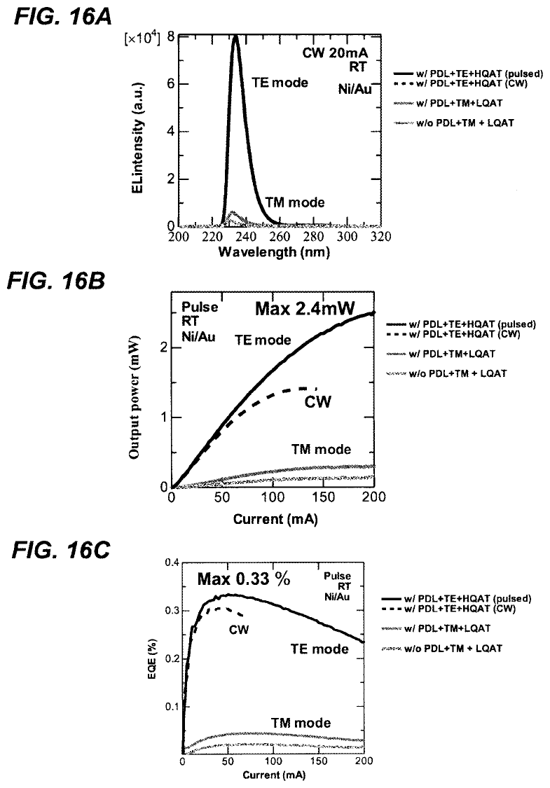

The inventors confirmed that good performance could be achieved by improving the electrical characteristics. Specifically, the inventors investigated the effect of adopting a p-GaN contact layer, which does not absorb UV light, from the perspective of prioritizing the electrical characteristics of the ohmic contact of the reflective electrode 160, which uses Ni/Au. Although this structure has the potential to reduce the light extraction efficiency (LEE), which is one of the factors that affect the external quantum efficiency (EQE), it aims to improve the power conversion efficiency (WPE, wall-plug efficiency). In this structure, a second p-type doped layer (thickness 20 nm) was followed by a p-GaN contact layer (thickness 40 nm, not shown in the figure) at the position of the second p-type doped layer 152 in FIG. 2. As a result, a maximum external quantum efficiency of 0.33% was obtained. To the best of the inventor's knowledge, there are no reported cases of an external quantum efficiency of 0.33% for an LED at 232 nm employing a p-GaN contact layer, except for the 0.5% case described in 4-1-2 above. FIGS. 16A-16C show the EL intensity spectra (FIG. 16A), current-light output characteristics (FIG. 16B), and current external quantum efficiency characteristics (FIG. 16C) obtained for sample examples that adopt the p-GaN contact layer of the embodiment of the present disclosure. These are shown in comparison with samples (labeled “w/ PDL+TM+LQAT” and “w/o PDL+TM+LQAT”) that do not employ the optimization of the quantum well layer structure for increasing the TE mode ratio (described above in section 4-1-1). The curves labeled “w/ PDL+TE+HQAT (pulsed)” and “w/ PDL+TE+HQAT (CW)” indicate that PDL (polarization doping layer), i.e., composition gradient layer, optimization of quantum well layer structure for increasing TE mode ratio (as described above in section 4-1-1), and quality improvement of AlN template (High Quality AlN Template) is adopted. The expressions in parentheses refer to the performance of the device in pulsed operation (duty ratio: 10%, pulse width: sub-msec) and continuous operation. In the fabrication of these samples, the inventors applied optimization of the quantum well layer structure to increase the TE mode ratio, and measured samples that adopted the improvements to the AlN template and n-type conductive layer (described above in section 4-1-2). The curves labeled “w/ PDL+TM+LQAT” and “w/o PDL+TM+LQAT” are those of samples that do not employ the optimization of the quantum well layer structure for increasing the TE mode ratio structures were measured without applying optimization of the quantum well layer for increasing the TE mode ratio without applying improvement of the AlN template and the n-type conductive layer, and they are for structures that adopted PDL and did not adopt PDL (FIG. 3B), respectively. The WPE calculated from the sample with an external quantum efficiency of 0.33% shown in FIG. 16C was 0.066%. This was about two-thirds of the WPE (0.1%) for the sample with an external quantum efficiency of 0.5% shown in FIG. 15.

### 4-1-4. Increasing the Number of Quantum Well Layers

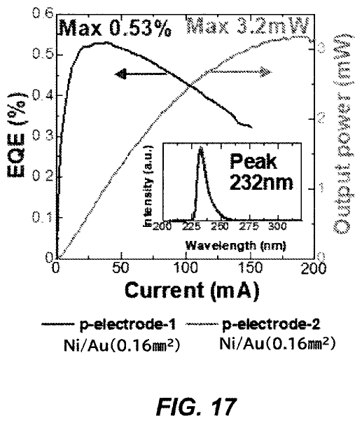

In order to further improve the structure described in section 4-1-2 (FIG. 15), the inventors created a sample of an LED with a structure in which the number of quantum well layers was increased from three to four. By changing the number of quantum wells from three to four, the maximum external quantum efficiency improved from 0.5% to 0.53%, and the output was 3.2 mW. In addition, the droop characteristic, in which the external quantum efficiency decreases as the current increases, became gentler. FIG. 17 is a graph showing the current external quantum efficiency and current light output characteristics measured from the sample of the present embodiment. The example sample from which the measurement values in FIG. 17 were obtained was fabricated by applying the optimization of the quantum well layer structure for increasing the TE mode ratio (as described above in Section 4-1-1) and the improvement of the AlN template and n-type conductive layer (as described in section 4-1-2). To the best of the inventor's knowledge, there is no previous example of a maximum external quantum efficiency of 0.53% at 232 nm.

### 4-1-5. Tuning of Modulation Doping and Composition Gradient

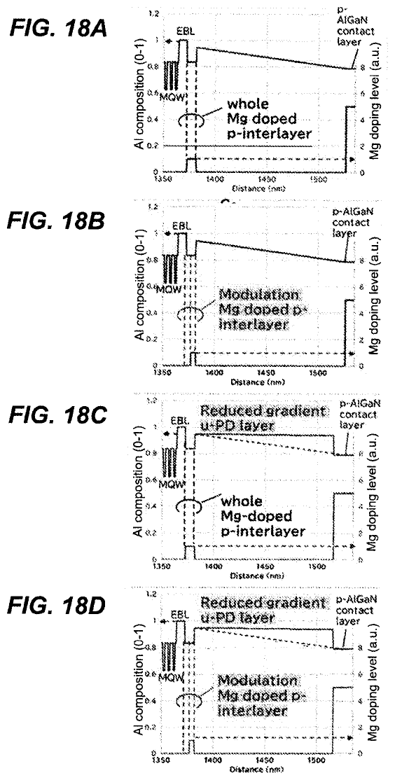

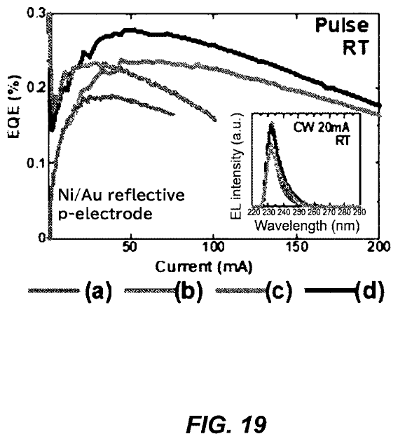

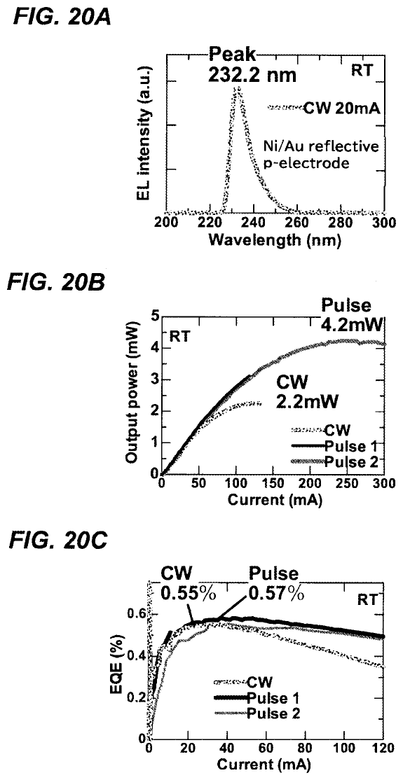

The inventors confirmed the improvement of the light-emitting diode described in the embodiments of the light-emitting diode (Sections 1 and 4-1 above). In the 230 nm LED with the LED 100 structure, modulation doping was employed in the first p-type doped layer 140 (FIG. 2). The modulation doping is a doping in which the concentration changes according to the local position in the thickness direction. The modulation doping can be performed by controlling the concentration of the raw material gas for the dopant (Mg) for p-type conduction that is mixed into the film-forming material according to the crystal growth. In this case, the composition gradient in the composition gradient layer 150 was also optimized. FIGS. 18A-18D are graphs showing the layer structure in terms of the Al composition ratio, showing: a structure similar to that of LED 100 (FIG. 18A); a structure in which the first p-type doped layer 140 is divided along the thickness direction, and Mg is modulated doped only to the composition gradient layer 150 side (FIG. 18B); one with a gentle composition gradient in the composition gradient layer 150 (FIG. 18C); and one with a combination of the modulation doping and gentle composition gradient as in FIG. 18B (FIG. 18D). FIG. 19 is a graph of the external quantum efficiency measured for samples of these structures. The labels (a) to (d) in FIG. 19 indicate that the samples correspond to FIGS. 18A to 18D, respectively. FIGS. 20A-20C show the performance measurement results for the structure shown in FIG. 18D, which combines modulated doping and a gentle composition gradient, and are graphs showing the EL spectrum (FIG. 20A), external quantum efficiency (FIG. 20B), and light output characteristics (FIG. 20C). The EL spectrum in FIG. 20A is from CW operation. FIGS. 20B and 20C show the results of pulse operation (Pulse 1) with a duty ratio of 10%, pulse width of sub-msec, and current range of 200 mA, as well as pulse operation (Pulse 2) with a duty ratio of 10%, pulse width of sub-msec, and current range of 500 mA, in addition to the CW operation. Furthermore, in the normal composition gradient of FIGS. 18A and 18B, the Al composition ratio was varied between 0.95 and 0.79 over the thickness of the composition gradient layer 150 of 144 nm, whereas in the gentle composition gradient of FIGS. 18C and 18D, the Al composition ratio was varied between 0.95 and 0.93. In addition, the sample used to obtain the measurement values in FIGS. 18A-D was fabricated by applying the optimization of the quantum well layer structure (described above in Section 4-1-1) to increase the TE mode ratio. As a result, the graph of external quantum efficiency shown in FIG. 19 was obtained. Furthermore, by applying the improvements to the AlN template and the n-type conductive layer (described above in Section 4-1-2), an example sample of the slow composition gradient and modulated doping shown in FIG. 18D was fabricated. As a result, the graph of external quantum efficiency shown in FIG. 20 was obtained.

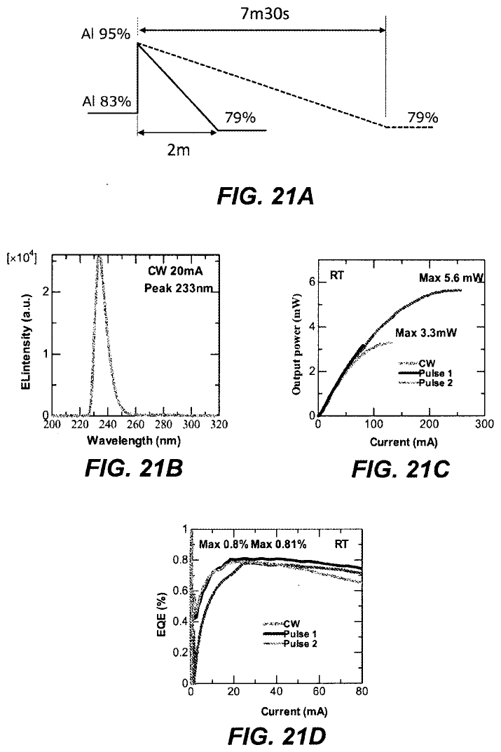

Additionally, samples with a steep composition gradient in the composition gradient layer 150 were also fabricated and their performance was investigated, in contrast to the gentle composition gradient. FIGS. 21A-D are graphs showing the case where a steep composition gradient and a normal composition gradient are adopted for the composition gradient layer 150, a time chart of the Al composition ratio during the growth process (FIG. 21A) and the results of performance measurements for the structure fabricated with the steep composition gradient, including EL spectra (FIG. 21B), external quantum efficiency (FIG. 21C), and light output characteristics (FIG. 21D). FIGS. 21B-21D show the performance measured under the same conditions as FIGS. 20A-20C described above. In FIG. 21A, the Al composition ratio of the composition gradient layer formed at each moment as the process progresses is shown on the vertical axis, and the horizontal axis shows the time matched to the start time of the composition gradient layer deposition process. It has been confirmed that the growth rate of the composition gradient layer (incremental thickness per unit time) is constant between the two conditions shown in the figure and at different times. Therefore, the horizontal axis in FIG. 21A can be linearly mapped to each position over the thickness direction of the composition gradient layer. In addition, the normal growth conditions for the composition gradient layer 150 in FIG. 21A are the same as those for the sample in FIG. 18A, which has the same structure as LED 100.

As shown in FIG. 21A, the Al composition ratio was varied from 0.95 to 0.79 for both the steep composition gradient and the normal composition gradient. However, for the steep composition gradient, the growth time of 7 minutes and 30 seconds was shortened to 2 minutes, so that the thickness was approximately ¼ of that for the normal composition gradient (thickness 144 nm), as shown by the solid line. Specifically, for the steep composition gradient, the Al composition ratio was set to 0.83 (83%) for the first p-type doped layer 140, and when this was complete, the Al composition ratio was set to 0.95 for the composition gradient layer 150. After that, the Al composition ratio is decreased linearly over a period of two minutes to reach 0.79, and the Al composition ratio is set to 0.79 for the second p-type doped layer 152. In the case of the normal composition gradient, the same rate of decrease in the Al composition ratio was used for the composition gradient layer 150, as shown by the dashed line, and the same amount of time was spent, but in the case of the steep composition gradient, the process time was shortened. As a result, the thickness of the composition gradient layer 150 in the case of the steep composition gradient was approximately 38.4 nm. In addition, the first p-type doped layer 140 was doped with Mg over the entire thickness direction of the first p-type doped layer 140, as in the sample shown in FIG. 18A. In the preparation of the sample used to obtain the measurement values in FIGS. 21B-D, the optimization of the quantum well layer structure for increasing the TE mode ratio (described above in Section 4-1-1) and the improvement of the AlN template and n-type conductive layer (described above in Section 4-1-2) were also applied. In the preliminary experimental stage, the inventors also produced a sample (not shown) that did not adopt the improved AlN template described in section 4-1-2 used a composition gradient layer 150 that was made thinner due to the steep composition gradient, but the ratio of wholesome samples (yield) was significantly reduced.

In the sample with modulated doping and a gentle composition gradient (FIG. 18D) and the sample with constant doping and a steep composition gradient (FIG. 21A), the results were as shown in Table 3, when compared with the sample in FIG. 18A with constant doping and a normal composition gradient.

TABLE 3

| | Modulated | Constant | Constant |
|---|---|---|---|
| | Doping & | Doping & | Doping & |
| | Gentle Comp. | Steep Comp. | Normal Comp. |
| | Gradient | Gradient | Gradient |
| | (FIG. 18D) | (FIG. 21A) | (FIG. 18A) |
| Max. Optical | 4.2 | 5.6 | 3.2 |
| Output, pulse | | | |
| (mW) | | | |
| Max. Optical | 2.2 | 3.3 | 1.7 |
| Output, | | | |
| CW(mW) | | | |
| Max. EQE, | 0.57 | 0.81 | 0.49 |
| pulse (%) | | | |
| Max. EQE, | 0.55 | 0.80 | 0.46 |
| CW (%) | | | |

To summarize, the combination of modulated doping and slow composition slope resulted in a maximum external quantum efficiency EQE of approximately 1.1 times for pulsed operation and approximately 1.17 times for continuous operation. The combination of modulation doping and a gentle composition gradient improved the maximum efficiency by 1.2 times compared to the combination of constant doping and a normal composition gradient. In addition, the maximum external quantum efficiency EQE was approximately 1.65 times higher for pulse operation and approximately 1.74 times higher for continuous operation when constant doping was combined with a steep composition gradient. On the other hand, the combination of constant doping and a steep composition slope resulted in a 1.74-fold increase in the maximum efficiency compared to the combination of constant doping and a normal composition slope. The performance of a 232 nm-band LED with an external quantum efficiency of 0.57% and an output of 4.2 mW (combination of modulated doping and gentle composition gradient) and external quantum efficiency of 0.81% and output of 5.6 mW (combination of constant doping and steep composition gradient) are, to the best of the inventor's knowledge, without precedent.

In order to explain the characteristics of each sample, the explanation given here is limited to whether the gradient of the Al composition ratio profile over the thickness direction of the composition gradient layer 150 is gentle or steep. If the gradient of the Al composition ratio is adjusted, the minimum value of the Al composition ratio will necessarily increase (in the case of a gentle composition gradient), the thickness of the composition gradient layer 150 will decrease (in the case of a steep composition gradient), and the discontinuous step amount of the Al composition ratio between the layers before and after will also be adjusted. Alternatively, it is also possible that the current with a component in the in-plane direction of the film formation is affected by the gradient. The features that can be adjusted in relation to the composition gradient layer 150 include the profile of the Al composition ratio of the composition gradient layer 150 and other features of the composition gradient layer 150 itself, as well as the relative features of the composition gradient layer 150 as seen from the preceding and following layers.

Any change in characteristics associated with adjusting the gradient can be an attribute for characterizing the UV light-emitting device of the present embodiment.

### 4-2. Supplementary Information on the Embodiment of the Laser Diode

The inventors have produced a sample of the LD 200, which has a light emission wavelength of around 280 nm as described in the embodiment of the laser diode (Section 2 above).

### 4-2-1. Measurement of Current Injection Amount

In the sample used in the experiment, the inventors confirmed the upper limit of the current injection amount that can be injected as a guide for lasing operation. The sample of the LD 200 used in the experiment was fabricated under the conditions shown in Table 4 below, and the resonator structure was completed.

TABLE 4

| | Al Composition | Thickness | |
|---|---|---|---|
| Layer (with ref numeral in FIG. 11) | Ratio (Content) | (nm) | Note |
| n-type cladding layer 232 | 0.65 | 2100 | Si doped |
| n-side WG layer 233 | 0.54 | 70 | undoped |
| barrier layer 23B | 0.54 | 6 | undoped |
| quantum well layer 23W | 0.36 | 3 | undoped |
| FB layer 23F | 0.54 | 1.2 | undoped |
| electron blocking layer 238 | 0.63 | 6 | undoped |
| p-side WG layer 240 | 0.54 | 70 | Mg doped |
| composition gradient layer 250 | 0.97~0.61 | 327 | constant gradient |
| additional composition gradient layer 251 | 0.61~0.00 | 43 | constant gradient |
| p-type GaN Layer 252 | 0.00 | 10 | Mg doped |

The resonator structure was formed by dry etching a total of 40 ridge structures. More specifically, there were eight types of resonator widths (20, 15, 12, 10, 8, 6, 5, and 4 μm), and five types of resonator lengths (1200, 1000, 700, 500, and 400 μm), and each resonator width and each resonator length were combined. The electrode (second electrode) 260 was formed using the vacuum deposition method with Ni/Au and V/Al/Ni/Au electrodes. After that, SiO₂ film deposition, mirror surface formation by ICP etching and wet etching using TMAH aqueous solution, and window opening for contact were performed, and a Ti/Au gold pad was formed for the p electrode.

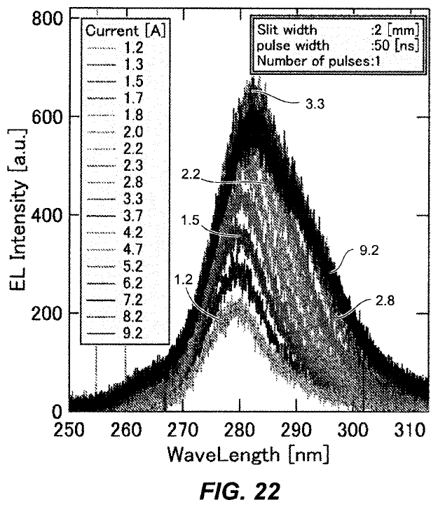

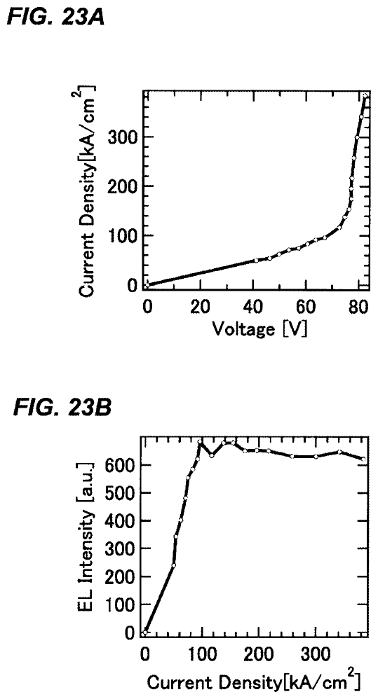

FIG. 22 shows the EL spectra for each current value measured for a sample of the LD 200. FIG. 22 is an observation of the EL spectrum for a fabricated LD sample, with current injection performed at room temperature and in pulse operation. The observation was made in a 10 μm×400 μm resonator. When the current value was increased in a stepwise manner, it was possible to inject a current of up to a maximum current density of 383 kAcm⁻². As shown in FIG. 22, the peak wavelength was 282 nm, and luminescence in the quantum well was confirmed. FIGS. 23A and 23B show the current-voltage characteristics (FIG. 23A) and current-luminescence intensity characteristics (FIG. 23B) measured using the same sample as FIG. 22. Up to a current density of 100 kA/cm², the performance of the device was observed to increase in light output in proportion to the injection current. On the other hand, at current densities above 100 kA/cm², the light output was saturated, and there was a possibility that carrier overflow had occurred. The current injection performance at a high current density of 383 kAcm⁻² considering that lasing operation is achieved at a current density of around 1 kAcm⁻² in a normal LD, it can be said that there are no particular problems with p-type conduction for LDs that perform lasing operation in the 280 nm wavelength range. In addition, lasing was not confirmed in any of the 40 samples.

### 4-2-2. Revisiting the Structure of the P-Side Waveguide (WG) Layer

The structure of layers between the active layer 234 and the composition gradient layer 250 in the LD 200 was further developed by optimizing the impurity concentration in the p-side WG layer 240, as explained in Section 2-2. When Mg, a p-type dopant, is added to the p-side WG layer 240, it is generally expected to be advantageous electrically because it improves the electrical performance, but it is expected to be disadvantageous optically because it makes it easier for the UV light that has been radiated and is confined to the high refractive index region to be scattered, etc. Moreover, the electron blocking layer 238 (FIGS. 10 and 11) has a higher Al composition ratio than the front and rear FB layers 23F and p-side WG layer 240, and as a result, the refractive index is reduced. Therefore, the electron blocking layer 238 may also be advantageous electrically but disadvantageous optically. In order to investigate these trade-off relationships in more detail, in addition to the examination in Section 2-2, the structure on the electrode 260 side was re-examined from the perspective of the active layer 234. In particular, the effect of modulation doping was investigated in a structure that did not employ an electron blocking layer 238, and the effect of modulation doping and the effect of modulation of the Al composition ratio were re-examined after employing an electron blocking layer 238.

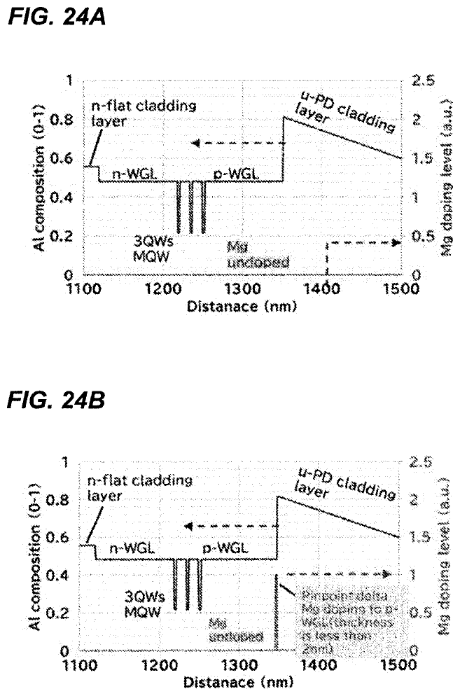

FIGS. 24A and 24B are graphs showing a layer structure by Al composition ratio in a structure without an electron blocking layer (EBL) in LD 200 designed to emit 280 nm ultraviolet rays; a structure in which the p-side waveguide (WG) layer 240 is undoped (FIG. 24A), and a structure with so-called delta doping, in which p-type dopants are doped in a very thin region adjacent to the composition gradient layer 250 in the p-side waveguide (WG) layer 240 (FIG. 24B). Since an electron blocking layer 238 is not used in typical LEDs, the structure without an electron blocking layer was first investigated as a control. For p-type doping, doping was carried out to a concentration of 1 a.u. (arbitrary unit) in a range of 2 nm in thickness, which is the usual level of concentration. The inventors measured the EL intensity of these samples to investigate their light-emitting behavior as LEDs. As a result, the external quantum efficiency was 0.02% for the sample without an electron blocking layer and undoped p-side WG layer 240, but it was improved to 0.24%, or more than 10 times, for the sample with sigma-doped p-type doping. The inventors believe that this improvement is attributable to the increased efficiency of electron injection, and that in the case of the sigma-doped p-type doping of very thin layers, optical differences are not likely to occur.

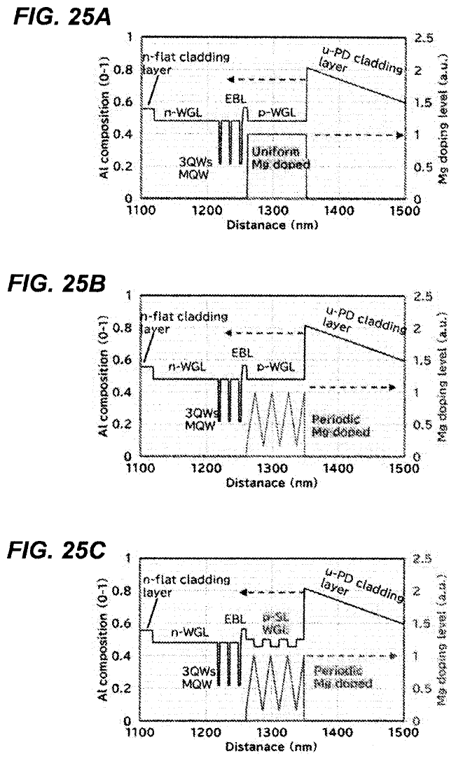

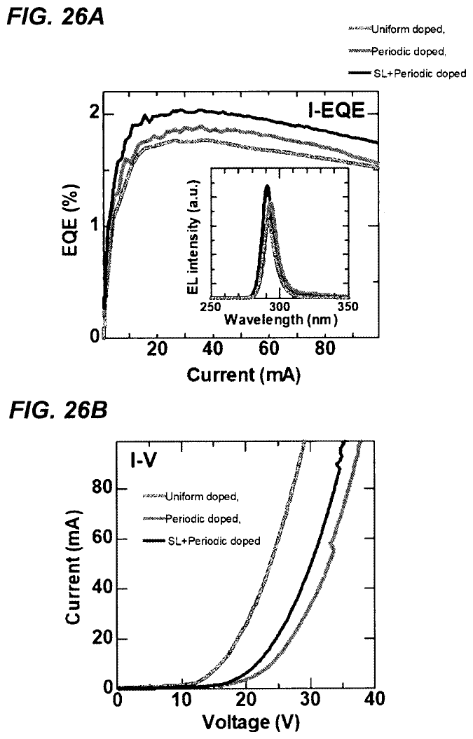

Next, the inventors investigated the effects of modulation doping and modulation of the Al composition ratio in the composition gradient layer 250, using the electron blocking layer 238. FIGS. 25A-25C are graphs showing the Al composition ratio in the LD 200: a structure in which p-type dopants are doped at a constant concentration over the thickness of the p-side WG layer 240 as in FIG. 11 (FIG. 25A); a structure in which p-type dopants are doped over the thickness of the p-side WG layer 240 in a concentration profile that is modulated by repeating increases and decreases (FIG. 25B); and a structure in which the Al composition ratio is repeatedly increased and decreased in addition to the repeated modulation of the p-type dopant (FIG. 25C). FIGS. 26A and 26B are graphs of the external quantum efficiency (FIG. 26A) and current-voltage characteristics (FIG. 26B) measured for each sample of the structures in FIGS. 25A to 25C.

As shown in FIGS. 26A and 26B, by performing modulation doping in the p-side WG layer 240 and adopting a modulation method of repeatedly increasing and decreasing the Al composition ratio, it was possible to improve the emission efficiency in an LD with a wavelength range of 280 nm. This improvement effect is about 1.2 times at maximum. The inventors believe that this improvement is due to an increase in the injection efficiency.

### 5. Conclusion

The inventors have now explained the specific structure of embodiments of the present disclosure. The above embodiments and structure are provided for the purpose of providing examples. In addition, variations may exist within the scope of the present disclosure, including other combinations of the embodiments.

### Industrial Applicability

The UV light-emitting device with improved luminous efficiency of this disclosure is used in any device that has it as a UV light source.

### REFERENCE SIGNS LIST

100 light-emitting diode (LED)
102 light-extraction surface
104 one side of the substrate
110 substrate
120 buffer layer
132 n-type conductive layer
134 emission layer
13W quantum well layer
13B barrier layer
13F FB layer
138 electron blocking layer
140 first p-type doped layer
150 composition gradient layer
152 second p-type doped layer
160 reflective metal electrode (reflective electrode, second electrode)
162 insert metal layer
164 UV reflective film
170 first electrode
200 laser diode (LD)
204 one side
232 n-type cladding layer
233 n-side waveguide (WG) layer
234 active layer
23W quantum well layer
23B barrier layer
23F FB layer
238 electron blocking layer
240 p-type waveguide (WG) layer
250 composition gradient layer
251 additional composition gradient layer
252 p-type GaN layer (second doped layer)
260 electrode (second electrode)

The various embodiments described above can be combined to provide further embodiments. All of the patents, applications, and publications referred to in this specification and/or listed in the Application Data Sheet are incorporated herein by reference, in their entirety. Aspects of the embodiments can be modified, if necessary to employ concepts of the various patents, applications, and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled.

1. A UV light-emitting device that includes an AlGaN-based crystal or an InAlGaN-based crystal, comprising:
in a layer stack of the following order in a flow direction of electrons:
an emission layer;
at least one electron blocking layer;
a first p-type doped layer; and
a composition gradient layer having an aluminum (Al) composition ratio that varies according to a position over a thickness direction of the layer stack.

2. The UV light-emitting device as claimed in claim 1,
wherein the direction of the electron flow is [0001] axis direction of the AlGaN-based crystal or the InAlGaN-based crystal, and
wherein a composition distribution of the composition gradient layer has a gradient such that the Al composition ratio decreases in accordance with the position from a side of the first p-type doped layer.

3. The UV light-emitting device as claimed in claim 2,
wherein the Al composition ratio of the first p-type doped layer is smaller than an Al composition ratio of the side of the composition gradient layer closest to the first p-type doped layer.

4. The UV light-emitting device as claimed in claim 2, further comprising a second p-type doped layer in contact with the composition gradient layer,
wherein the Al composition ratio of the second p-type doped layer is substantially equal to the Al composition ratio of the side of the composition gradient layer closest to the second p-type doped layer.

5. The UV light-emitting device as claimed in claim 1,
wherein a minimum value of the Al composition ratio of the composition gradient layer is determined so that an absorption edge wavelength of the composition gradient layer is shorter than an emission peak wavelength of the emission layer.

6. The UV light-emitting device as claimed in claim 1,
wherein the AlGaN-based crystal or InAlGaN-based crystal of the UV light-emitting device is grown on a substrate with different material, and
wherein the composition gradient layer is an undoped layer.

7. The UV light-emitting device as claimed in claim 6, wherein he composition gradient layer is arranged to cover protrusions or pits that can cause columnar defects in the AlGaN-based crystal or InAlGaN-based crystal.

8. The UV light-emitting device as claimed in claim 1,
wherein the at least one electron blocking layer includes a multiple quantum barrier layer.

9. The UV light-emitting device as claimed in claim 3, further comprising:
an n-type cladding layer doped with n-type; and
an n-type core layer doped with n-type,
wherein the n-type cladding layer, the n-type core layer, the emission layer, the electron blocking layer, the first p-type doped layer, and the composition gradient layer are stacked in this order,
wherein the UV light-emitting device has an end face for emitting light of a waveguide mode that propagates in a direction that intersects over the thickness direction, and
wherein the UV light-emitting device is operated as a UV laser light emitting element.

10. The UV light-emitting device as claimed in claim 1, wherein a principal wavelength of the UV light emitted is 210 to 240 nm.

11. The UV light-emitting device as claimed in claim 1, further comprising a reflective metal electrode located downstream of the composition gradient layer in the flow direction of the electrons,
wherein the reflective metal electrode is either a Ni/Al composite layer or a Rh single layer.

12. The UV light-emitting device as claimed in claim 9, wherein the principal wavelength of the emitted UV light is 250 nm to 300 nm.

13. An electronic appliance having the UV light-emitting device as claimed in claim 1.

14. The UV light-emitting device as claimed in claim 1, wherein the emission layer includes multiple quantum well layers,
wherein the thickness of the quantum well layers is 3 nm or less.

15. The UV light-emitting device as claimed in claim 14, wherein the emission layer includes multiple quantum well layers,
wherein the thickness of the quantum well layers is 1.5 nm.

16. The UV light-emitting device as claimed in claim 4, further comprising:
a p-type GaN layer in contact with the second p-type doped layer; and
a metal electrode in contact with the p-type GaN layer.

17. The UV light-emitting device as claimed in claim 1, wherein the emission layer comprises three or more quantum well layers.

18. The UV light-emitting device as claimed in claim 17, wherein the emission layer comprises four quantum well layers.

19. The UV light-emitting device as claimed in claim 1, wherein a p-type dopant concentration of the first p-type doped layer is modulated according to a position in the first p-type doped layer.

20. The UV light-emitting device as claimed in claim 19, wherein the p-type dopant concentration of the first p-type doped layer is high at the position on the side of the composition gradient layer in the first p-type doped layer and low at the position on the side of the at least one electron blocking layer.

21. The UV light-emitting device as claimed in claim 1, wherein the first p-type doped layer does not contain p-type dopants in a part of the position in the first p-type doped layer on the side of the at least one electron blocking layer, and contains p-type dopants in another part of the position on the side of the composition gradient layer.

22. A UV light-emitting device having an AlGaN-based crystal or an InAlGaN-based crystal, comprising:
in a layer stack of the following order in a flow direction of electrons:
an n-type cladding layer doped with n-type;
an n-type core layer doped with n-type;
an emission layer;
a first p-type doped layer; and
a composition gradient layer having an aluminum (Al) composition ratio that varies according to a position in a thickness direction of the layer stack,
wherein an Al composition ratio of the first p-type doped layer is smaller than an Al composition ratio of a side closest to the first p-type doped layer of the composition gradient layer, and
wherein a p-type dopant concentration of the first p-type doped layer is modulated according to a position in the first p-type doped layer,
wherein the UV light-emitting device has an end face for emitting light of a waveguide mode that propagates in a direction intersecting over the thickness direction, and
wherein the UV light-emitting device is operated as a UV laser emission element.

23. The UV light-emitting device as claimed in claim 22, wherein the first p-type doped layer includes p-type dopants in a part of the composition gradient layer side in the first p-type doped layer, and does not include p-type dopants in a remaining part of the first p-type doped layer.

24. The UV light-emitting device as claimed in claim 22, further comprising at least one electron block layer between the emission layer and the first p-type doped layer,
wherein a p-type dopant concentration of the first p-type doped layer is modulated according to a position in the first p-type doped layer.

25. The UV light-emitting device as claimed in claim 24, wherein a p-type dopant concentration of the first p-type doped layer is modulated to repeatedly increase and decrease according to the position in the first p-type doped layer.

26. The UV light-emitting device as claimed in claim 25, wherein an Al composition ratio of the first p-type doped layer is modulated to repeatedly increase and decrease according to the position in the first p-type doped layer.
